(19) United States
(12) Patent Application Publication
(10) Pub. No.: US 2025/0374631 A1
(43) Pub. Date: Dec. 4, 2025

(54) Structure and Method for Semiconductor Devices with Interposer and Post Clean Process

(71) Applicant: Taiwan Semiconductor Manufacturing Company, Ltd., Hsin-Chu (TW)

(72) Inventors: Hua-Yuan HUANG, New Taipei City (TW); Tsu-Hui SU, Taipei City (TW)

(21) Appl. No.: 18/933,707

(22) Filed: Oct. 31, 2024

Related U.S. Application Data
(60) Provisional application No. 63/655,238, filed on Jun. 3, 2024.

(51) Int. Cl. H01L 29/66; H01L 21/02; H01L 21/3065; H01L 29/06; H01L 29/423; H01L 29/775; H01L 29/786

(52) U.S. Cl. CPC H10D 64/017; H01L 21/02057; H01L 21/3065; H10D 30/014; H10D 30/43; H10D 30/6735; H10D 30/6757; H10D 62/121; H10D 64/021

(57) ABSTRACT

The present disclosure provides a method that includes forming a stack including first semiconductor layers and second semiconductor layers over a substrate, the first and second semiconductor layers alternating with one another; forming a dummy gate structure over the stack; selectively removing the second semiconductor layers of the stack, resulting in first gaps among the first semiconductor layers; depositing a first dielectric material to fill in the first gaps; performing a first etching process to the first dielectric material to form dielectric interposers; performing a first cleaning process using a first cleaning chemical solution; performing a second etching process to laterally recess the dielectric interposers, resulting in second gaps among the first semiconductor layers; and performing a second cleaning process using a second cleaning chemical solution being different from the first cleaning chemical solution.

### PRIORITY

This application claims the benefit to U.S. Provisional Application Ser. No. 63/655,238 filed Jun. 3, 2024, the entire disclosures of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing, and for these advancements to be realized, similar developments in IC processing and manufacturing are needed.

For example, multi-gate devices have been introduced in an effort to improve gate control by increasing gate-channel coupling, reduce OFF-state current, and reduce short-channel effects (SCEs). One such multi-gate device is a gate-all-around (GAA) transistor, whose gate structure extends around its channel region, thereby providing access to the channel region on all sides. Such GAA transistors are compatible with conventional complementary metal-oxide-semiconductor (CMOS) processes, allowing them to be aggressively scaled down while maintaining gate control and mitigating SCEs. However, conventional methods for GAA devices may experience challenges, including epitaxial loss in the source/drain region, variation of channel lengths, and weak regions of gate electrodes, and gate work function shifting, especially as device size is scaled down. Therefore, although conventional GAA devices have been generally adequate for their intended purposes, they are not satisfactory in every respect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 1C are flow charts of an example method for fabricating an embodiment of a GAA device according to some embodiments of the present disclosure;

FIGS. 2A to 6A and 8A to 16A are top views of embodiments of GAA devices of the present disclosure constructed at various fabrication stages according to some embodiments of the present disclosure;

FIGS. 2B to 6B and 8B to 16B are cross sectional views of embodiments of GAA devices of the present disclosure along the line A-A′ in FIGS. 2A to 6A and 8A to 16A, respectively, according to some embodiments of the present disclosure;

FIGS. 2C to 6C and 8C to 16C are cross sectional views of an embodiment of a GAA device of the present disclosure along the line B-B′ in FIGS. 2A to 6A and 8A to 16A, respectively, according to some embodiments of the present disclosure;

FIGS. 2D to 6D and 8D to 16D are cross sectional views of an embodiment of a GAA device of the present disclosure along the line C-C′ in FIGS. 2A to 6A and 8A to 16A, respectively, according to some embodiments of the present disclosure;

FIGS. 7A to 7I are cross-sectional views of example methods for fabricating various embodiments of a GAA device according to some embodiments of the present disclosure; and

FIG. 7J illustrates a table of cleaning chemical solutions according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” may encompass the dimension range from 4.5 nm to 5.5 nm.

Multi-gate devices (e.g. gate-all-around (GAA) devices) have been introduced in an effort to improve gate control by increasing gate-channel coupling, reduce OFF-state current, and reduce short-channel effects (SCEs). GAA devices can be aggressively scaled down while maintaining gate control and mitigating SCEs. However, conventional methods for GAA devices may experience challenges, including poor epitaxial growth in the source/drain region, small formation margin for gate dielectric and electrode in the narrow channel-channel spaces, channel degradations related to various etch residues and defects. These drawbacks are exacerbated as device size is scaled down.

The present disclosure is generally related to ICs and semiconductor devices and methods of forming the same. More particularly, the present disclosure is related to GAA devices. A GAA device includes any device that has its gate structure, or portions thereof, formed around all-sides of a channel region (e.g. surrounding a portion of a channel region). In some instances, a GAA device may also be referred to as a quad-gate device where the channel region has four sides and the gate structure is formed on all four sides. The channel region of a GAA device may include one or more semiconductor layers, each of which may be in one of many different shapes, such as wire (or nanowire), sheet (or nanosheet), bar (or nano-bar), and/or other suitable shapes. In embodiments, the channel region of a GAA device may have multiple horizontal semiconductor layers (such as nanowires, nanosheets, or nano-bars) (hereinafter collectively referred to as “nanochannels”) vertically spaced, making the GAA device a stacked horizontal GAA device. The GAA devices presented herein may be a complementary metal-oxide-semiconductor (CMOS) GAA device, a p-type metal-oxide-semiconductor (pMOS) GAA device, an n-type metal-oxide-semiconductor (nMOS) GAA device, or a complementary field-effect transistor (CFET) having nMOS and pMOS transistors vertically stacked. Further, the GAA devices may have one or more channel regions associated with a single, contiguous gate structure, or multiple gate structures. One of ordinary skill may recognize other examples of semiconductor devices that may benefit from aspects of the present disclosure. For example, other types of metal-oxide semiconductor field effect transistors (MOSFETs), such as planar MOSFETs, FinFETs, other multi-gate FETs may benefit from the present disclosure. The GAA devices and methods of manufacture that are proposed in the present disclosure exhibit desirable properties, examples being: (1) a process using dummy interposer or dummy oxide interposer (DOI); (2) various cleaning processes designed to eliminate or reduce etch residues or defects; and (3) increased channel dimensions and improved channel profile.

In the illustrated embodiments, the IC device includes a device structure (or GAA device or workpiece) 100. The device structure 100 may be fabricated during processing of the IC, or a portion thereof, that may include static random access memory (SRAM) and/or logic circuits, passive components such as resistors, capacitors, and inductors, and active components such as p-type field effect transistors (pFETs), n-type FETs (nFETs), FinFETs, MOSFETs, CMOS, bipolar transistors, high voltage transistors, high frequency transistors, other memory cells, and combinations thereof.

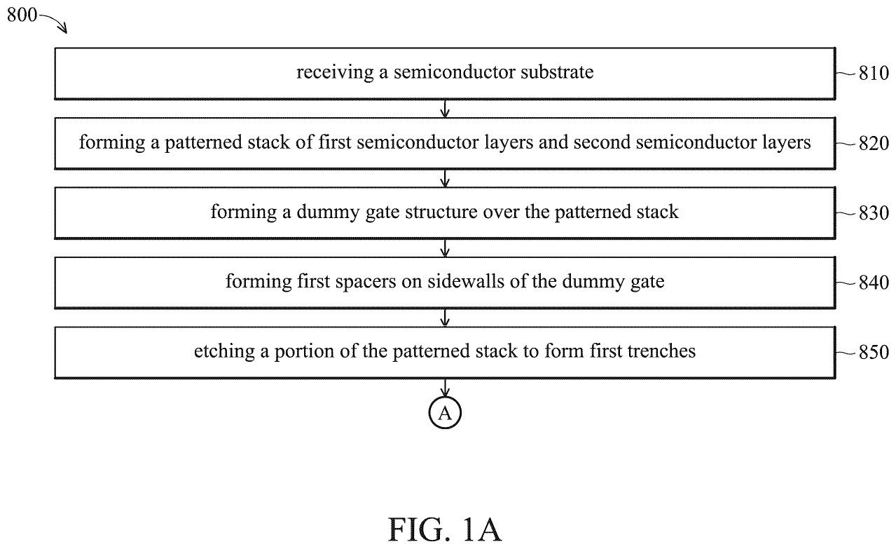

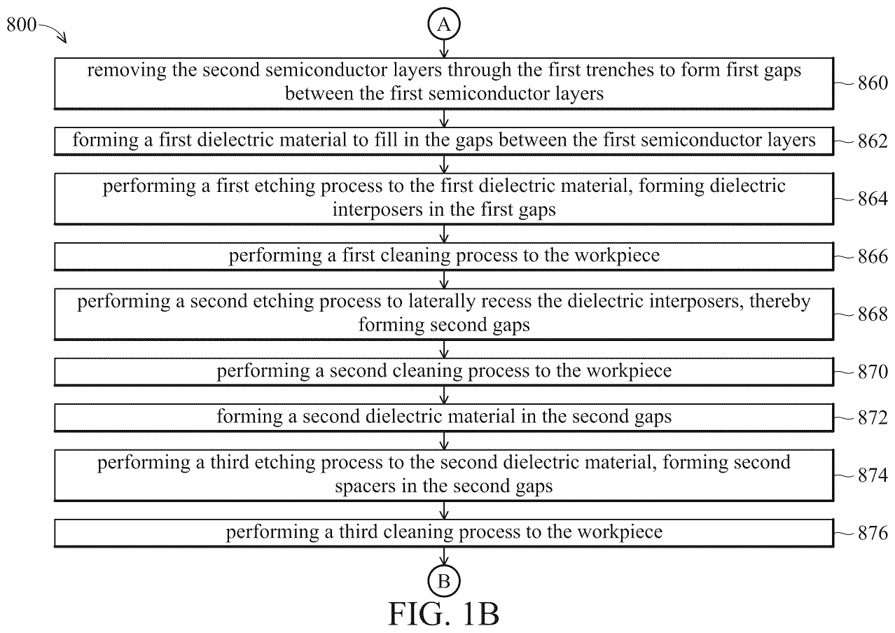

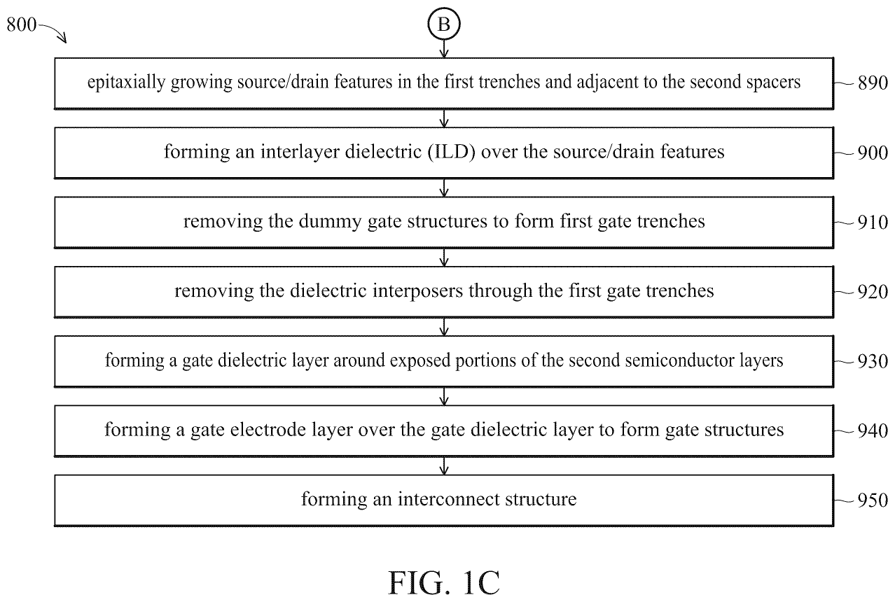

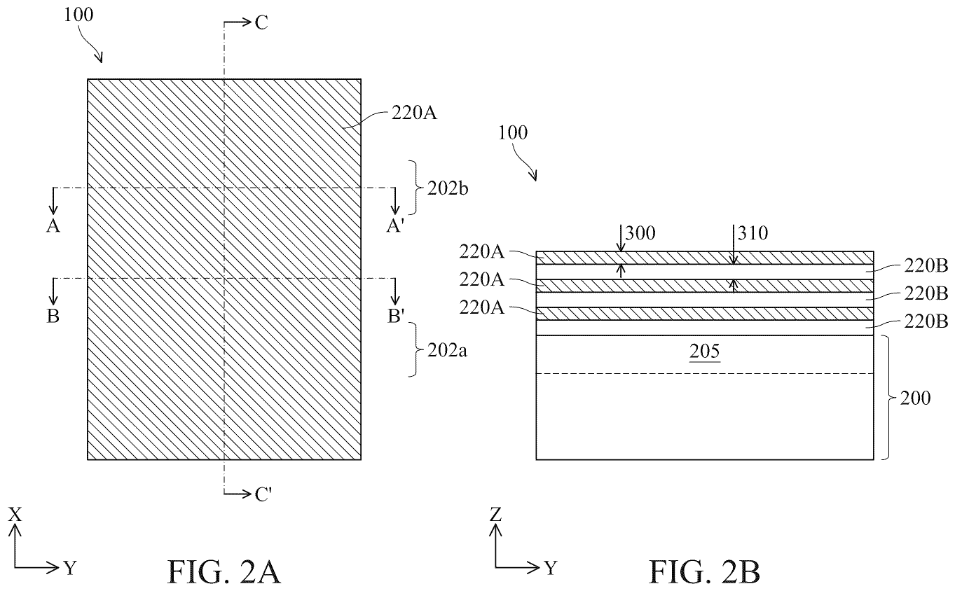

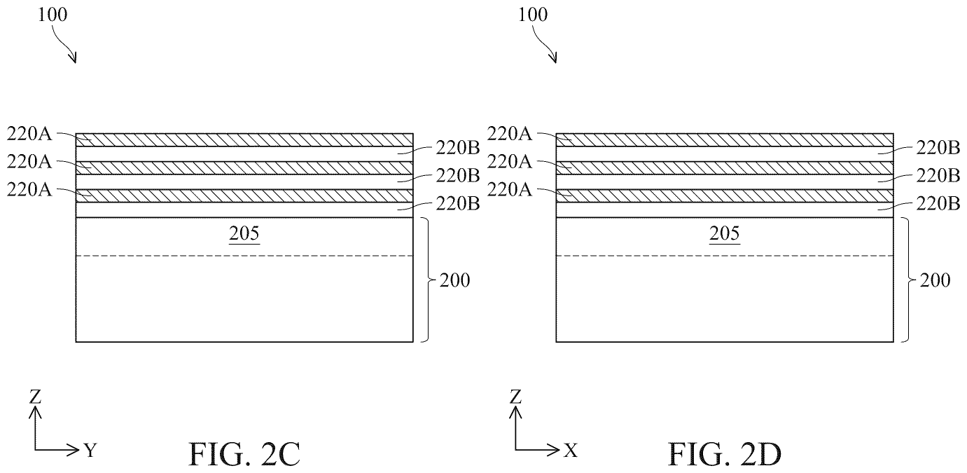

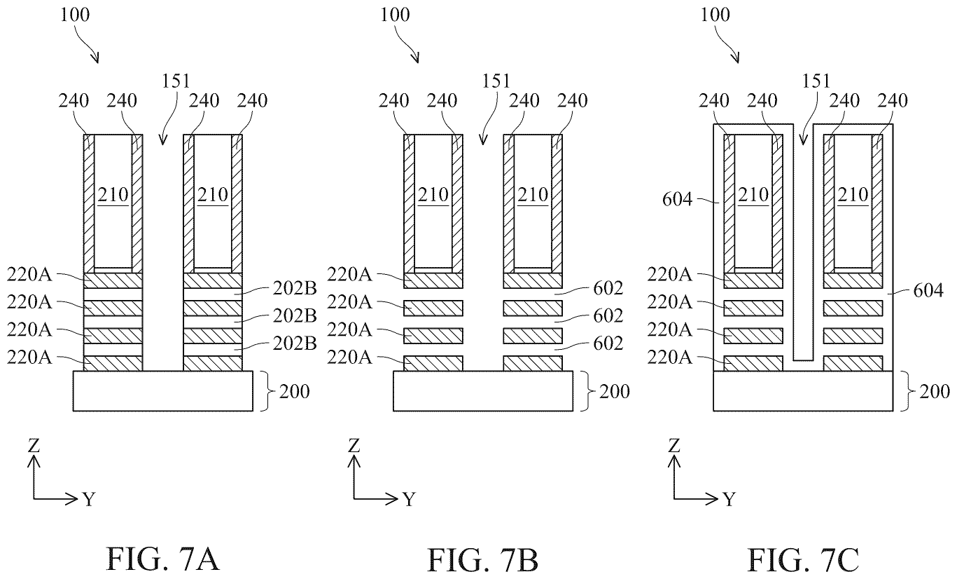

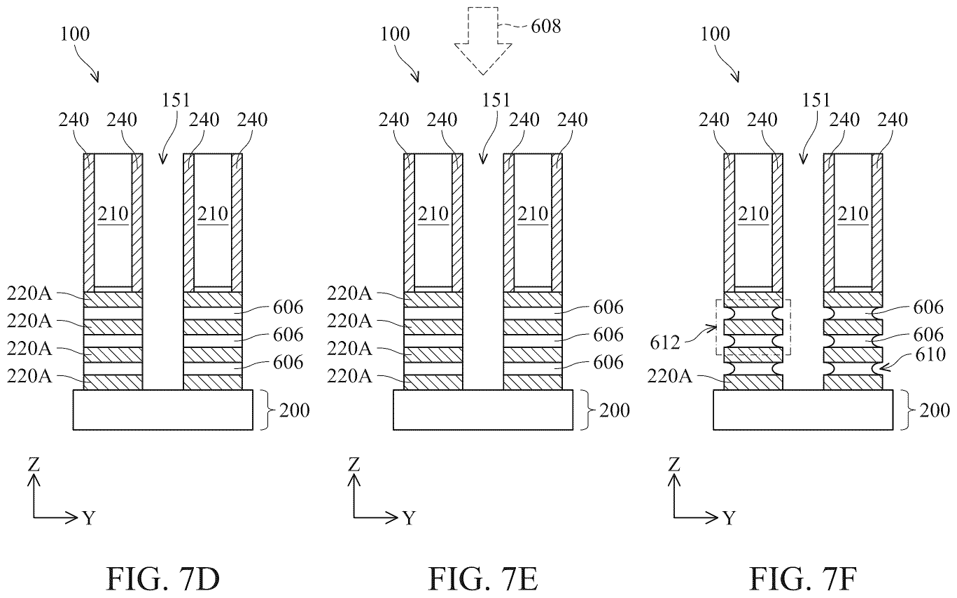

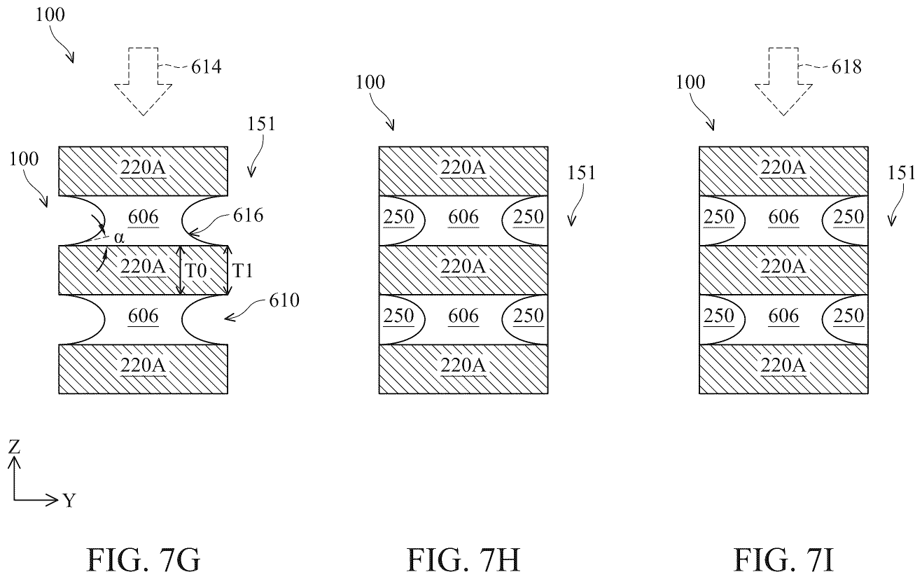

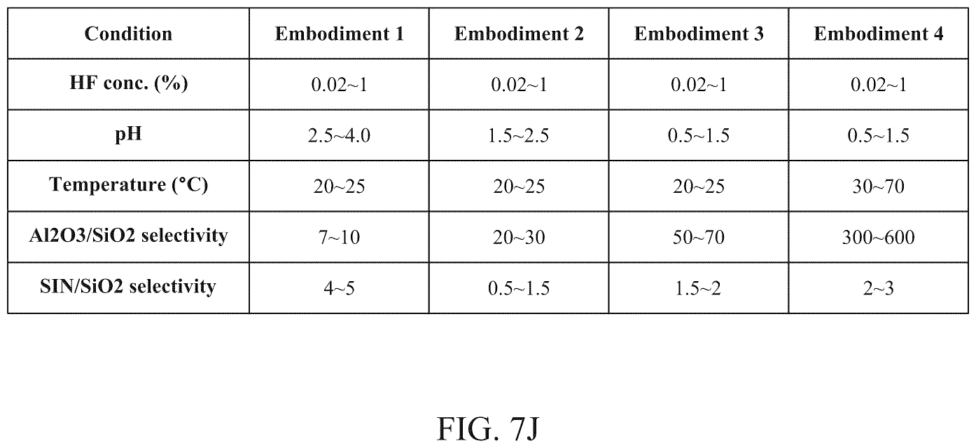

FIGS. 1A-1C are flowcharts of an example method for fabricating an embodiment of 2A to 6A and 8A to 16A are top views of an embodiment of a device structure of the present disclosure constructed at various fabrication stages according to some embodiments of the present disclosure. FIGS. 2B to 6B and 8B to 16B, FIGS. 2C to 6C and 8C to 16C, FIGS. 2D to 6D and 8D to 16D are cross sectional views of an embodiment of a device structure of the present disclosure along the lines A-A′, B-B′, and C-C′ in FIGS. 2A to 6A and 8A to 16A, respectively, according to some embodiments of the present disclosure. FIGS. 7A to 7I are cross-sectional views of example methods for fabricating various embodiments of a device structure according to some embodiments of the present disclosure. FIG. 7J illustrates a table of cleaning chemical solutions according to various embodiments.

Referring to block 810 of FIG. 1A and FIGS. 2A-2D, the device structure 100 includes a substrate 200. In some embodiments, the substrate 200 contains a semiconductor material, such as bulk silicon (Si). Alternatively or additionally, another elementary semiconductor, such as germanium (Ge) in a crystalline structure, may also be included in the substrate 200. The substrate 200 may also include a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb), or combinations thereof. The substrate 200 may also include a semiconductor-on-insulator substrate, such as Si-on-insulator (SOI), SiGe-on-insulator (SGOI), Ge-on-insulator (GOI) substrates. Portions of the substrate 200 may be doped, such as the doped portions 205. The doped portions 205 may be doped with p-type dopants, such as boron (B) or boron fluoride (BF₃), or doped with n-type dopants, such as phosphorus (P) or arsenic (As). The doped portions 205 may also be doped with combinations of p-type and n-type dopants (e.g. to form a p-type well and an adjacent n-type well). The doped portions 205 may be formed directly on the substrate 200, in a p-well structure, in an n-well structure, in a dual-well structure, or using a raised structure.

Referring to block 820 of FIG. 1A and FIGS. 2A-2D, a stack of semiconductor layers 220A and 220B are formed over the substrate 200 in an interleaving or alternating fashion, extending vertically (e.g. along the Z-direction) from the substrate 200. For example, a semiconductor layer 220B is disposed over the substrate 200, a semiconductor layer 220A is disposed over the semiconductor layer 220B, another semiconductor layer 220B is disposed over the semiconductor layer 220A, so on and so forth. In the depicted embodiments, there are three layers of semiconductor layers 220A and three layers of semiconductor layers 220B alternating between each other. However, there may be any appropriate number of layers in the stack. For example, there may be 2 to 10 layers of semiconductor layers 220A, alternating with 2 to 10 layers of semiconductor layers 220B in the stack. For convenience, the semiconductor layers 220A and 220B are also referred to as the first semiconductor layers 220A and the second semiconductor layers 220B, respectively. The material compositions of the semiconductor layers 220A and 220B are configured such that they have an etching selectivity in a subsequent etching process. For example, in some embodiments, the semiconductor layers 220A contain silicon germanium (SiGe), while the semiconductor layers 220B contain silicon (Si). In some other embodiments, the semiconductor layers 220B contain SiGe, while the semiconductor layers 220A contain Si. In the depicted embodiment, each of the semiconductor layers 220A has a substantially uniform thickness, depicted in FIG. 2B as the thickness 300, while each of the semiconductor layers 220B has a substantially uniform thickness, depicted in FIG. 2B as the thickness 310.

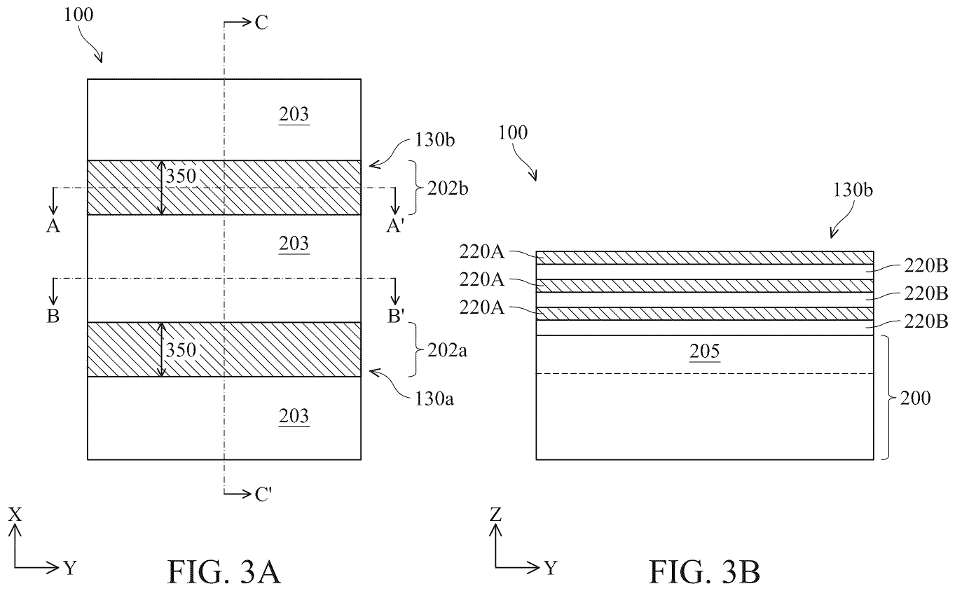

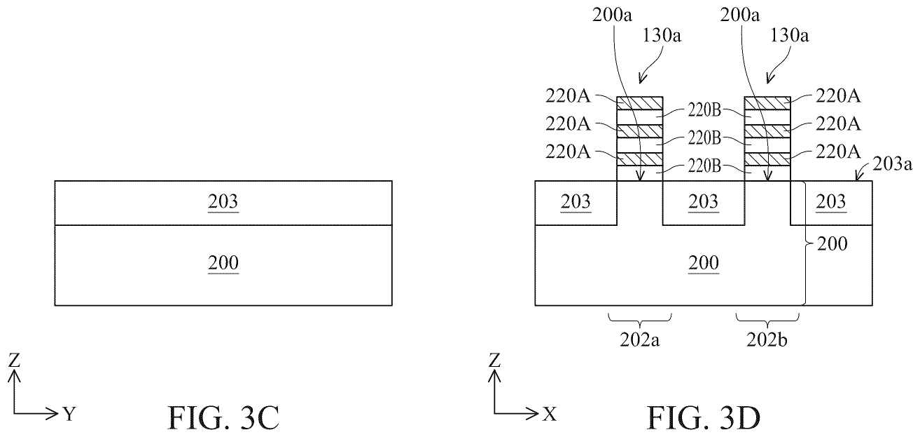

Referring to block 820 of FIG. 1A and FIGS. 3A-3D, the stack of semiconductor layers 220A and 220B are patterned into a plurality of fin structures, for example, into fin structures (or fins) 130a and 130b. Each of the fins 130a and 130b includes a stack of the semiconductor layers 220A and 220B disposed in an alternating manner with respect to one another. The fins 130a and 130b each extends lengthwise (e.g. longitudinally) in a first direction (e.g. in the Y-direction) and are separated from each other (e.g. laterally) in a second direction (e.g. in the X-direction), as shown in FIGS. 3A and 3D. As illustrated in FIG. 3A, the fins may each have a lateral width along the X-direction, depicted in FIG. 3A as the width 350. It is understood that the X-direction and the Y-direction are horizontal directions that are perpendicular to each other, and that the Z-direction is a vertical direction that is orthogonal (or normal) to a plane defined by the X-direction and the Y-direction. The substrate 200 may have its top surface aligned in parallel to the XY plane. In some embodiments, the fin 130a and fin 130b have different widths.

The fins 130a and 130b may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins. The patterning may utilize multiple etching processes which may include a dry etching and/or wet etching. The regions in which the fins are formed will be used to form active devices through subsequent processing and are thus referred to as active regions. For example, fin 130a is formed in the active region 202a, and the fin 130b is formed in the active region 202b. Both fins 130a and 130b protrude out of the doped portions 205.

The device structure 100 includes isolation features 203, which may be shallow trench isolation (STI) features. In some examples, the formation of the isolation features 203 includes etching trenches into the substrate 200 between the active regions and filling the trenches with one or more dielectric materials such as silicon oxide, silicon nitride, silicon oxynitride, other suitable materials, or combinations thereof. Any appropriate methods, such as a chemical vapor deposition (CVD) process, an atomic layer deposition (ALD) process, a physical vapor deposition (PVD) process, a plasma-enhanced CVD (PECVD) process, a plasma-enhanced ALD (PEALD) process, and/or combinations thereof may be used for depositing the isolation features 203. The isolation features 203 may have a multi-layer structure such as a thermal oxide liner layer over the substrate 200 and a filling layer (e.g., silicon nitride or silicon oxide) over the thermal oxide liner layer. Alternatively, the isolation features 203 may be formed using any other isolation formation techniques. As illustrated in FIG. 3D, the fins 130a and 130b are located above the top surface 203a of the isolation features 203 (e.g. protrude out of the isolation features 203) and are also located above the top surface 200a of the substrate 200. In some embodiments, the fins 130a/130b and the isolation features 203 are collectively formed in a same procedure, such as a procedure that includes patterning the stack of semiconductor layers 220A and 220B to from fins and trenches; filling the trenches with one or more dielectric materials; performing a chemical mechanical polishing (CMP) process; and etching back the isolation features 203 such that the isolation features 203 are recessed below the fins 130a and 130b.

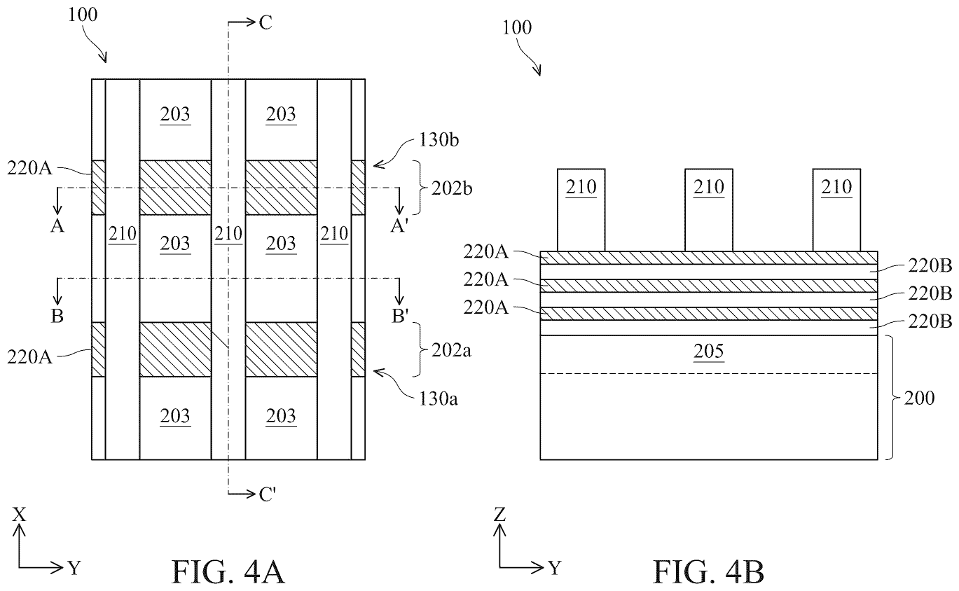

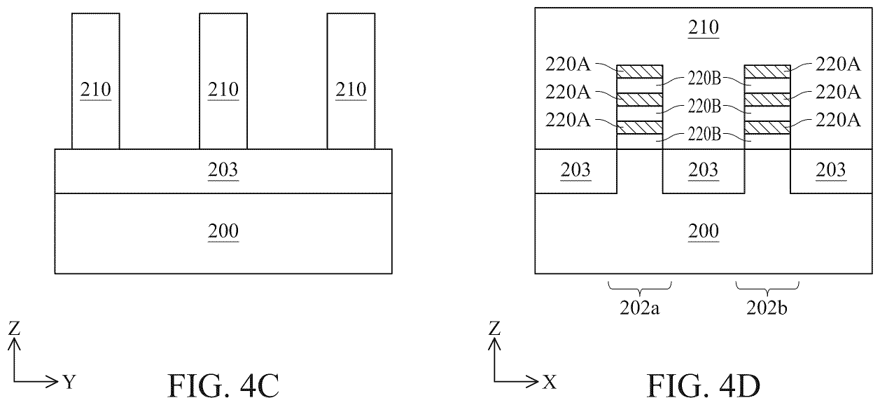

Referring to block 830 of FIG. 1A and FIGS. 4A-4D, dummy gate structures 210 are formed over a portion of each of the fins 130a and 130b, and over the isolation features 203, in between the fins 130a and 130b. The dummy gate structures 210 may be configured to extend lengthwise (e.g. longitudinally) in parallel to each other, for example, each along the X-direction, as shown in FIG. 4A. In some embodiments, as illustrated in FIG. 4D, each of the dummy gate structures wraps around the top surface and side surfaces of each of the fins 130a, 130b. The dummy gate structures 210 may include polysilicon. In some embodiments, the dummy gate structures 210 also include one or more mask layers, which are used to pattern the dummy gate electrode layers. The dummy gate structures 210 may undergo a gate replacement process through subsequent processing to form metal gates, such as a high-k metal gate, as discussed in greater detail below. Some of the dummy gate structures 210 may also undergo a second gate replacement process to form a dielectric based gate that electrically isolates the GAA device 100 from neighboring devices, as also discussed in greater detail below. The dummy gate structures 210 may be formed by a procedure including deposition, lithography patterning, and etching processes. The deposition processes may include CVD, ALD, PVD, other suitable methods, and/or combinations thereof.

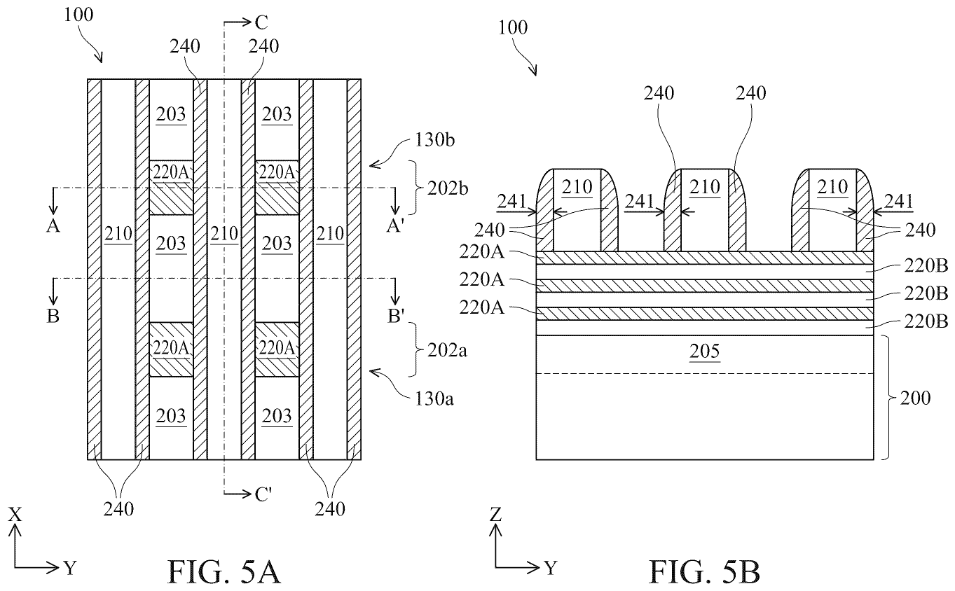

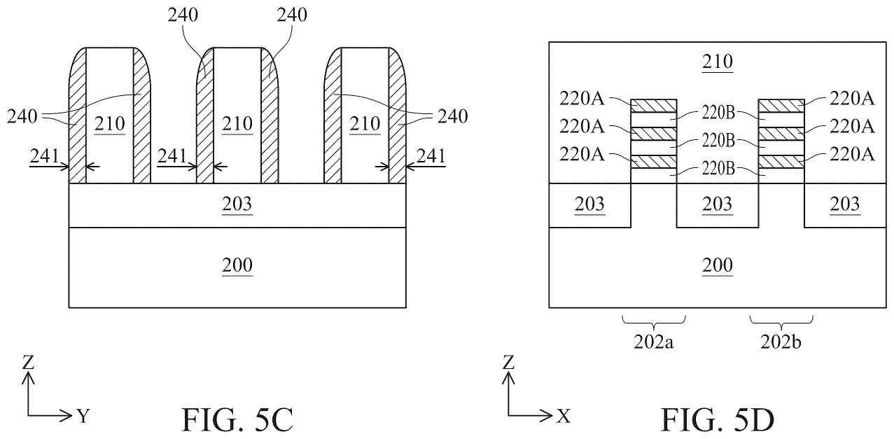

Referring to block 840 of FIG. 1A and FIGS. 5A-5D, gate spacers (or first spacers) 240 are formed on the sidewalls of the dummy gate structures 210. The gate spacers 240 may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, other suitable dielectric material, or combinations thereof. The gate spacers 240 may include a single layer or a multi-layer structure. In some embodiments, each of the gate spacers 240 may have a thickness 241 (e.g. measured in the Y-direction) in a range from about 3 nm to about 10 nm. A thickness within the stated range of values may be needed for device performance, especially for advanced technology nodes. In some embodiments, the gate spacers 240 may be formed by depositing a spacer layer (containing the dielectric material) over the dummy gate structures 210, followed by an anisotropic etching process to remove portions of the spacer layer from the top surfaces of the dummy gate structures 210. After the etching process, portions of the spacer layer on the sidewall surfaces of the dummy gate structures 210 substantially remain and become the gate spacers 240. In some embodiments, the anisotropic etching process is a dry (e.g. plasma) etching process. Additionally or alternatively, the formation of the gate spacers 240 may also involve chemical oxidation, thermal oxidation, ALD, CVD, and/or other suitable methods. In the active regions, the gate spacers 240 are formed over the top layer of the semiconductor layers 220A. Accordingly, the gate spacers 240 may also be interchangeably referred to as the top spacers 240. In some examples, one or more material layers (not shown) may also be formed between the dummy gate structures 210 and the corresponding top spacers 240. The one or more material layers may include an interfacial layer and/or a high-k dielectric layer, as examples.

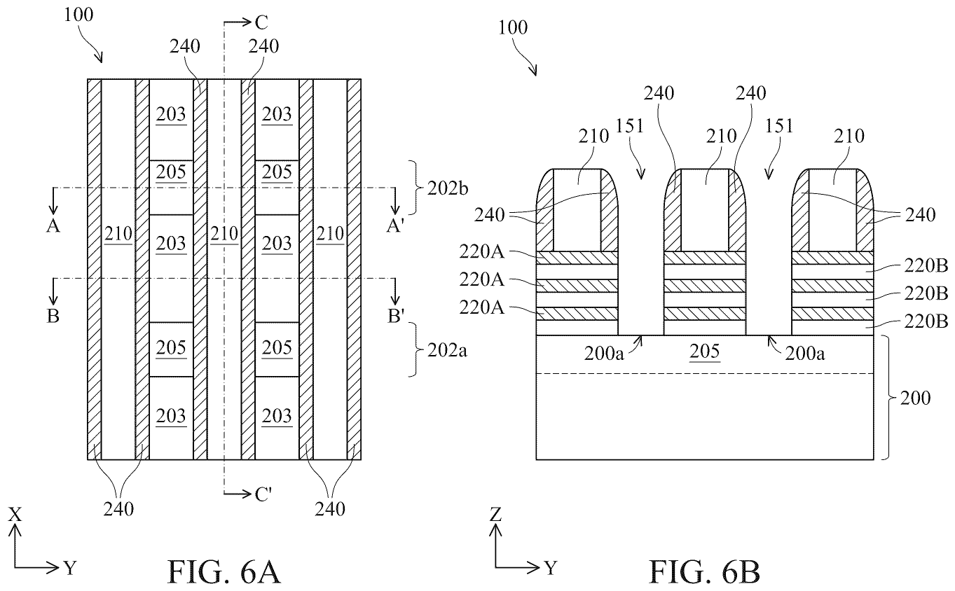

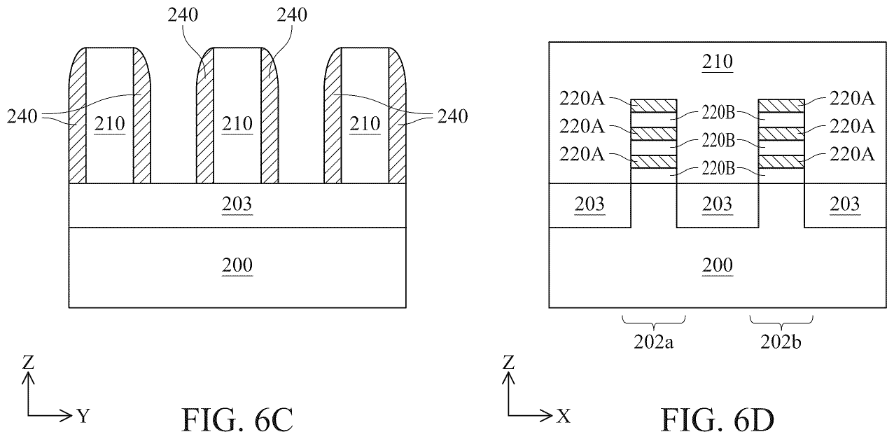

Referring to block 850 of FIG. 1A and FIGS. 6A-6D, portions of the fins 130a and 130b exposed by the dummy gate structures 210 and the gate spacers 240 are at least partially recessed (or etched away) to form trenches 151 for subsequent epitaxial source and drain growth. The process used to form the trenches 151 may include one or multiple lithography and etching steps, and may use any suitable methods, such as dry etching and/or wet etching. As an example, one or more of the multiple lithography and etching steps used to form the trenches 151 may include a first etch process having a first etch chemistry and a second etch process having a second etch chemistry that is different from the first etch chemistry. The first etch process may be a main-etch process that initially forms an opening in the stack of semiconductor layers 220A and 220B, while the second etch process may be an over-etch process that shapes the initially-formed opening to produce the desired profile of the trenches 151, such as the trenches having vertical sidewalls. The first etch chemistry may include hydrogen bromide (HBr) combined with argon (Ar), helium (He), oxygen (O₂), or a combination thereof. The second etch chemistry may include hydrogen bromide (HBr) combined with nitrogen, methane (CH₄), or a combination thereof. The second etch process (e.g. the over-etch process) may be performed at a high bias power (e.g. a bias power in a range from about 200 Watts to about 400 Watts).

The method 800 proceeds to operations 860 through 874 in FIGS. 7A through 7I, which are associated with processing steps applied in the trenches 151 and designed to reduce the residues and enhance the channel performance. Only FIGS. 7A through 7I in sectional views along AA′ are illustrated for simplicity. Especially, the operations 860 through 874 begin with FIG. 7A, which is similar to FIG. 6B, although the number of the semiconductor layers 220A and the number of the semiconductor layers 220B may be different. As noted above, there may be any appropriate number of layers in the stack.

Referring to block 860 of FIG. 1B and FIG. 7B, the semiconductor layers 220B are removed through the trenches 151 via a selective etching process, resulting in first gaps 602 between the semiconductor layers 220A. The selective etching process may be any suitable processes, such as a wet etching or a dry etching process. In an embodiment, the semiconductor layers 220A includes Si and the semiconductor layers 220B includes SiGe. In such an embodiment, a Standard Clean 1 (SC-1) solution may be used to selectively etch away the SiGe semiconductor layers 220B. For example, the SiGe semiconductor layers 220B may be etched away at a substantially faster rate than the Si semiconductor layers 220A. As a result, the semiconductor layers 220B (e.g. the side portions 220B-side) are removed, while the semiconductor layers 220A remain substantially unchanged. The SC-1 solution includes ammonia hydroxide (NH₄OH), hydrogen peroxide (H₂O₂), and water (H₂O). The optimal condition may be reached by additionally adjusting the etching temperature, dopant concentration, as well as other experimental parameters.

In another embodiment, the semiconductor layers 220A include SiGe and the semiconductor layers 220B includes Si. In such an embodiment, a cryogenic deep reactive ion etching (DRIE) process may be used to selectively etch away the Si semiconductor layer 220B. For example, the DRIE process may implement a sulfur hexafluoride-oxygen (SF₆—O₂) plasma. The optimal condition may be reached by adjusting the etching temperature, the power of the Inductively Coupled Plasma (ICP) power source and/or Radio Frequency (RF) power source, the ratio between the SF₆ concentration and the O₂ concentration, the dopant (such as boron) concentrations, as well as other experimental parameters. For example, the etching rate of a Si semiconductor layer 220B using a SF₆—O₂ plasma (with approximately 6% O₂) may exceed about 8 μm/min at a temperature of about −80° C.; while the SiGe semiconductor layers 220A are not substantially affected during the process.

Referring to block 862 of FIG. 1B and FIG. 7C, one or more dielectric material 604 is deposited to fill in the first gaps 602. The dielectric material 604 is deposited on sidewalls of the trenches 151, the sidewalls of the gate spacers 240 and the top of the gate structures 210. In some embodiments, the dielectric material 604 includes silicon oxide, silicon nitride, silicon oxynitride, any suitable dielectric material, or a combination thereof.

In some embodiments, the dielectric material 604 includes silicon oxide. The dielectric material 604 of silicon oxide may be formed by CVD, low pressure chemical vapor deposition (LPCVD), atmospheric pressure chemical vapor deposition (APCVD), flowable CVD (FCVD), thermal oxidation, other suitable method, or a combination thereof. In some examples, silicon oxide is formed by CVD using a precursor including silane (SiH₄) and oxygen (O2), alternatively further including PH3 or B2H6 as dopants. The deposition temperature ranges between 400° C. and 500° C. In some examples, silicon oxide is formed by LPCVD using a precursor including tetraethoxysilane Si(OC2H5) 4 (TEOS) and oxygen (O₂) with a deposition temperature around 700° C., such as in a range between 650° C. and 750° C. In some examples, silicon oxide is formed by PECVD using a precursor including TEOS and ozone (03) with a deposition temperature ranging between 300° C. and 350° C. In some examples, silicon oxide is formed by PECVD using a precursor including SiH4 and N2O with a deposition temperature ranging between 200° C. and 450° C. In some examples, silicon oxide is formed by APCVD using a precursor including TEOS and O3 with a deposition temperature ranging between 350° C. and 500° C. In some examples, silicon oxide is formed by thermal oxidation PECVD using a precursor including SiH4 and N2O with a deposition temperature ranging between 200° C. and 450° C.

In the disclosed embodiment, the dielectric material layer 604 includes silicon oxide and is formed by a procedure that includes CVD and FCVD. For example, a CVD is applied to form a thin silicon oxide layer, and FCVD is applied thereafter to form another silicon oxide to completely fill the first gaps 602. In furtherance of the embodiment, the first deposition step includes forming a first silicon oxide layer by CVD using a precursor including silane (SiH4) and oxygen (O2) with a deposition temperature ranging between 400° C. and 500° C.; and the second deposition step includes forming a second silicon oxide layer by FCVD with details described below.

The FCVD process may include the deposition of a silicon-and-nitrogen containing film (e.g., a silicon-nitrogen-hydrogen (Si—N—H) film) from a carbon-free silicon-and-nitrogen precursor and radical precursor. Because the silicon-and-nitrogen film is formed without carbon, the conversion of the film into hardened silicon oxide is done with less pore formation and less volume shrinkage. The conversion of the silicon-and-nitrogen film to silicon oxide may be done by heating the silicon-and-nitrogen film in an oxygen-containing atmosphere. The oxygen-containing gases in this atmosphere may include radical atomic oxygen (O), molecular oxygen (O2), ozone (O3), and/or steam (H₂O), among other oxygen-containing gases. The heating temperatures, times, and pressures are sufficient to oxidize the silicon-and-nitrogen film into the silicon oxide film.

Referring to block 864 of FIG. 1B and FIG. 7D, an etching process (also referred to as a first etching process) is applied to the dielectric material 604, thereby removing the portions of the dielectric material 604 deposited on the sidewalls of the trenches 151, resulting in the dielectric interposers (or dummy oxide interposers) 606 in the first gaps 602. The method includes an anisotropic etch, such as a plasma etch, with etching substantially on the vertical direction. In furtherance of the embodiment, the plasma etch includes an etchant having fluorine-containing gas, chlorine-containing gas, other suitable gas or a combination thereof.

Referring to block 866 of FIG. 1B and FIG. 7E, a first wet cleaning process 608 using a first cleaning chemical solution is applied to the workpiece 100 to remove any residues, such as metal residues after the first etching process at block 864. The experiments found that the metal residues are left on the etching surface due to effective etching process. Furthermore, the existing cleaning process causes damages to the dielectric interposers 606, resulting in defects, such as voids, on the dielectric interposers 606. Other issues may also present. For example, the first semiconductor layers 220A, eventually functioning as channels of the GAA transistors, are further degraded, such as reducing the dimensions of the portions exposed to the cleaning solution. The end portions of the first semiconductor layers 220A are reduced by the cleaning solution with round corners and less dimension, which further degrades the GAA device performance and the threshold voltage. Accordingly, the present disclosure, through various experiments, identifies the cleaning solutions, and the cleaning process conditions and parameters to be implemented at this step and other subsequent steps to be described later.

In the disclosed embodiments, the first cleaning chemical solution includes hydrofluoric acid (HF), water (H2O), and one or more pH adjuster. In some embodiments, the cleaning solution includes hydrofluoric acid (HF) with a volume concentration (volume ratio as a ratio of a volume of the corresponding chemical to the volume of the total cleaning solution) ranging between 0.02% and 20%, water (H2O) with a volume concentration ranging between 60% and 99.8%, and one of a base pH adjuster and an acid pH adjuster. In some embodiments, the base adjuster includes ammonium hydroxide (NH₄OH) with a volume concentration ranging between 0% and 20%, so to tune the pH value of the cleaning solution to a pH value ranging between 5 and 12. In some embodiments, the acid adjuster includes hydrogen chloride (HCl), phosphoric acid (H3PO4), sulfuric acid (H2SO4), or a combination thereof, with a volume concentration ranging between 0% and 20%, so to tune the pH value of the cleaning solution to a pH value ranging between 1 and 6. In furtherance of the embodiments, the cleaning solution includes a temperature ranging between 5° C. and 80° C. when it is applied to the workpiece 100.

In one embodiment, the first cleaning solution includes hydrofluoric acid (HF) with a volume concentration (volume ratio) ranging between 0.02% and 20%; water (H2O) with a volume concentration ranging between 60% and 99.8%; and a base pH adjuster NH₄OH with a volume concentration ranging between 0% and 20% to tune the pH value of the cleaning solution to a pH value ranging between 5 and 12, and furthermore with a solution temperature ranging between 5° C. and 80° C. In another embodiment, the cleaning solution includes hydrofluoric acid (HF) with a volume concentration (volume ratio) ranging between 0.02% and 20%; water (H2O) with a volume concentration ranging between 60% and 99.8%; and an acid pH adjuster containing hydrogen chloride (HCl), phosphoric acid (H3PO4), sulfuric acid (H2SO4), or a combination thereof, with a volume concentration ranging between 0% and 20% to tune the pH value of the cleaning solution to a pH value ranging between 1 and 6, and furthermore with a solution temperature ranging between 5° C. and 80° C.

Such prepared cleaning solution has a high selectivity and effectiveness to cleaning the workpiece 100 without damages to the dielectric interposers 606 and the first semiconductor layers 220A, and without metal residues. Furthermore, the cleaning solution (such as second and third cleaning solutions, described below) is further tuned to each cleaning steps for respective effectiveness.

Referring to block 868 of FIG. 1B and FIG. 7F, an etching process (also referred to as a second etching process) is applied to the dielectric interposers 606 so that the dielectric interposers 606 are laterally recessed through the exposed sidewall surfaces in the trenches 151 via a selective etching process. The selective etching process may be any suitable etching processes, such as a wet etching or a dry etching process. The extent to which the dielectric interposers 606 are recessed (or the size of the portion removed) is determined by the processing conditions such as the duration the dielectric interposers 606 is exposed to an etching chemical. In the depicted embodiments, the duration is controlled such that the side portions of the dielectric interposers 606 directly underlying the gate spacers 240 are removed in their entirety, while the center portions of the dielectric interposers 606 remain substantially unchanged. In other words, the remaining portions of the dielectric interposers 606 each has a sidewall that is substantially aligned with a sidewall of the dummy gate structures 210 (e.g. the sidewall in the XZ plane, defined by the X-direction and the Z-direction). As illustrated in FIG. 7F, the selective etching process creates recesses (also referred to as second gaps) 610, which extend the trenches 151 into areas beneath the semiconductor layers 220A and top spacers 240. Meanwhile, the semiconductor layers 220A are only slightly affected during the selective etching process. The etch selectivity between the first semiconductor layers 220A and the dielectric interposers 606 is made possible by the etchant and etching process. For example, the dielectric interposers 606 may be etched away at a substantially faster rate (e.g. more than about 5 times to about 10 times faster) than the first semiconductor layers 220A. In some embodiments, the etching process is wet etching with HF solution as etchant.

The following operations in FIG. 1B are described with reference to FIGS. 7G˜7I. FIGS. 7G˜7I are sectional views of the device structure 100 similar to FIGS. 7A˜7F but only in portion, such as only a portion in the dashed line box 612 of FIG. 7F being illustrated for simplicity.

Referring to block 870 of FIG. 1B and FIG. 7G, a second wet cleaning process 614 using a second cleaning chemical solution is applied to the workpiece 100 to remove any residues, such as metal residues after the second etching process at block 868 and prepare surfaces for the following processes. In the disclosed embodiments, the second cleaning chemical solution includes hydrofluoric acid (HF), water (H2O), and one or more pH adjuster. In some embodiments, the cleaning solution includes hydrofluoric acid (HF) with a volume concentration (volume ratio) ranging between 0.02% and 20%, water (H2O) with a volume concentration ranging between 60% and 99.8%, and one of a base pH adjuster and an acid pH adjuster. In some embodiments, the base adjuster includes ammonium hydroxide (NH₄OH) with a volume concentration ranging between 0% and 20%, so to tune the pH value of the cleaning solution to a pH value ranging between 5 and 12. In some embodiments, the acid adjuster includes hydrogen chloride (HCl), phosphoric acid (H3PO4), sulfuric acid (H2SO4), or a combination thereof, with a volume concentration ranging between 0% and 20%, so to tune the pH value of the cleaning solution to a pH value ranging between 1 and 6. In furtherance of the embodiments, the cleaning solution includes a temperature ranging between 5° C. and 80° C. when it is applied to the workpiece 100.

In one embodiment, the second cleaning chemical solution includes hydrofluoric acid (HF) with a volume concentration (volume ratio) ranging between 0.02% and 20%; water (H2O) with a volume concentration ranging between 60% and 99.8%; and a base pH adjuster NH₄OH with a volume concentration ranging between 0% and 20% to tune the pH value of the cleaning solution to a pH value ranging between 5 and 12, and furthermore with a solution temperature ranging between 5° C. and 80° C. In another embodiment, the cleaning solution includes hydrofluoric acid (HF) with a volume concentration (volume ratio) ranging between 0.02% and 20%; water (H2O) with a volume concentration ranging between 60% and 99.8%; and an acid pH adjuster containing hydrogen chloride (HCl), phosphoric acid (H3PO4), sulfuric acid (H2SO4), or a combination thereof, with a volume concentration ranging between 0% and 20% to tune the pH value of the cleaning solution to a pH value ranging between 1 and 6, and furthermore with a solution temperature ranging between 5° C. and 80° C.

Such prepared cleaning solution has a high selectivity and effectiveness to cleaning the workpiece 100 without damages to the dielectric interposers 606 and the first semiconductor layers 220A, and without metal residues. Furthermore, the third cleaning solution, described below, is further tuned for its effectiveness. However, the cleaning process at block 870 and the other subsequent cleaning process may be tuned different from that at block 866, which will be further described in detail later.

After the second etching process at block 868 and the second cleaning process at block 870, the second gaps 610 are formed between the first semiconductor layers 220A. Especially, the experiment date found that the first semiconductor layers 220A have no or minimal loss at the edges, as illustrated in FIG. 7G. The first semiconductor layers 220A keep the profile without rounding issue. Specifically, the first semiconductor layers 220A have a thickness TO at the main portions and a thickness T1 at the edges. The difference ΔT=T0-T1 is less than 2 nm. In other words, the loss ΔT is less than 2 nm if any. In some examples, the difference ΔT ranges between 0.1 nm and 1.5 nm. The top surfaces of the first semiconductor layers 220A are substantially coplanar with the X-Y plane. The edge portions of the first semiconductor layers 220A have top surfaces with an angle α to the X-Y plane. In the disclosed embodiment, the angle α is less than 20 degrees. In some examples, the angle α ranges between 0.1 degree and 20 degree. In some examples, the angle α ranges between 0.1 degree and 10 degree.

In some embodiments, the recessed sidewalls 616 of the dielectric interposers 606 have concaved surfaces as illustrated in FIG. 7G. In this case, each gap 610 between adjacent first semiconductor layers 220A has varying recessing dimensions along the Z direction from the underlying first semiconductor layer 220A to the overlying first semiconductor layer 220A. the maximum recessing dimension is at middle level between the underlying and overlying first semiconductor layers 220A.

Referring to block 872 of FIG. 1B and FIG. 7H, a dielectric material 250 is filled in the second gaps 610. The method to form the dielectric material 250 includes deposition using a suitable deposition technology. The dielectric material 250 is different from the composition of the dielectric interposers 606 to achieve etch selectivity during subsequent processes, such as during the channel-release operation. In some embodiments, the dielectric material 250 may be selected from SiON, SiOC, SiOCN, other suitable dielectric material or combinations thereof. In some embodiments, the proper selection of the dielectric material may be based on its dielectric constant. In an embodiment, the dielectric material 250 may have a dielectric constant lower than that of the top spacers 240. In some other embodiments, this dielectric material 250 may have a dielectric constant higher than that of the top spacers 240. This aspect of the dielectric material will be further discussed later. The deposition of the dielectric material may be any suitable methods, such as CVD, PVD, PECVD, MOCVD, ALD, PEALD, or combinations thereof.

Referring to block 874 of FIG. 1B and FIG. 7H, an etching process (also referred to as a third etching process) is applied the dielectric material 250 such that the dielectric material 250 formed on sidewalls of the trenches 151 is removed by the third etching process. The third etching process includes an anisotropic etch with substantially vertical etching so that the portions of the dielectric material 250 deposited on the sidewalls and bottom surface of the trenches 151 are removed. In the depicted embodiment, the third etching process is a self-aligned anisotropic dry-etching process, such that the top spacers 240 are used as the masking element. Alternatively, a different masking element (e.g. a photoresist) may be used. The third etching process removes the dielectric materials 250 within the trenches 151 but does not substantially affect the dielectric materials 250 within the second gaps 610. As a result, the dielectric material 250 fills in the second gaps 610 become inner spacers (or second spacers), being referred to with the numeral 250 as well. In other words, the inner spacers 250 are formed in the second gaps 610 between vertically adjacent (e.g. along in the Z-direction) side portions of the first semiconductor layers 220A.

Referring to block 876 of FIG. 1B and FIG. 7I, a third wet cleaning process 618 using a third cleaning chemical solution is applied to the workpiece 100 to remove any residues, such as metal residues after the third etching process at block 872 and prepare the surfaces for the following processes. In the disclosed embodiments, the third cleaning chemical solution includes hydrofluoric acid (HF), water (H2O), and one or more pH adjuster. In some embodiments, the cleaning solution includes hydrofluoric acid (HF) with a volume concentration (volume ratio) ranging between 0.02% and 20%, water (H2O) with a volume concentration ranging between 60% and 99.8%, and one of a base pH adjuster and an acid pH adjuster. In some embodiments, the base adjuster includes ammonium hydroxide (NH₄OH) with a volume concentration ranging between 0% and 20%, so to tune the pH value of the cleaning solution to a pH value ranging between 5 and 12. In some embodiments, the acid adjuster includes hydrogen chloride (HCl), phosphoric acid (H3PO4), sulfuric acid (H2SO4), or a combination thereof, with a volume concentration ranging between 0% and 20%, so to tune the pH value of the cleaning solution to a pH value ranging between 1 and 6. In furtherance of the embodiments, the cleaning solution includes a temperature ranging between 5° C. and 80° C. when it is applied to the workpiece 100.

In one embodiment, the third cleaning chemical solution includes hydrofluoric acid (HF) with a volume concentration (volume ratio) ranging between 0.02% and 20%; water (H2O) with a volume concentration ranging between 60% and 99.8%; and a base pH adjuster NH₄OH with a volume concentration ranging between 0% and 20% to tune the pH value of the cleaning solution to a pH value ranging between 5 and 12, and furthermore with a solution temperature ranging between 5° C. and 80° C. In another embodiment, the cleaning solution includes hydrofluoric acid (HF) with a volume concentration (volume ratio) ranging between 0.02% and 20%; water (H2O) with a volume concentration ranging between 60% and 99.8%; and an acid pH adjuster containing hydrogen chloride (HCl), phosphoric acid (H3PO4), sulfuric acid (H2SO4), or a combination thereof, with a volume concentration ranging between 0% and 20% to tune the pH value of the cleaning solution to a pH value ranging between 1 and 6, and furthermore with a solution temperature ranging between 5° C. and 80° C.

Such prepared cleaning solution has a high selectivity and effectiveness to cleaning the workpiece 100 without damages to the dielectric interposers 606 and the first semiconductor layers 220A, and without metal residues. Furthermore, the cleaning solution may be further tuned to each cleaning steps for respective effectiveness since each cleaning solution is applied at different surfaces and conditions. However, the third cleaning process at block 876 may be tuned different from the first cleaning process at block 866 and the second cleaning process at block 870, which will be further described below in detail later.

FIG. 7J provides a table of the cleaning process and the corresponding cleaning chemical solution according to various embodiments. The cleaning process and the corresponding cleaning chemical solution are tuned with different characteristics, therefore have different cleaning and removal selectivity suitable for different cleaning process. The table in FIG. 7J includes four embodiments of the cleaning process and the corresponding cleaning chemical solution. The first column lists various conditions, parameters and characteristics of the cleaning process and the corresponding cleaning chemical solution, which includes HF concentration (%, volume ratio) in the cleaning solution, pH value of the cleaning solution, the temperature of the cleaning solution, removal selectivity between Al2O3 and SiO2, and removal selectivity between SiN and SiO2. The removal selectivity between A and B is defined as ratio of the removal rate to A and the removal rate to B. In various embodiments, the pH value and temperature of the cleaning chemical solution are tuned differently and achieve significant changes to removal selectivity, as described below in detail.

In the first embodiment, the cleaning chemical solution includes HF with concentration ranging between 0.02% and 1%; a pH value ranging between 2.5 and 4.0; and a temperature ranging between 20° C. and 25° C. Accordingly, the corresponding cleaning chemical solution has a removal selectivity between Al₂O3 and SiO2 ranging between 7 and 10, and a removal selectivity between SiN and SiO2 ranging between 4 and 5.

In the second embodiment, the cleaning chemical solution includes HF with concentration ranging between 0.02% and 1%; a pH value ranging between 1.5 and 2.5; and a temperature ranging between 20° C. and 25° C. Accordingly, the corresponding cleaning chemical solution has a removal selectivity between Al₂O3 and SiO2 ranging between 20 and 30, and a removal selectivity between SiN and SiO2 ranging between 0.5 and 1.5.

In the third embodiment, the cleaning chemical solution includes HF with concentration ranging between 0.02% and 1%; a pH value ranging between 0.5 and 1.5; and a temperature ranging between 20° C. and 25° C. Accordingly, the corresponding cleaning chemical solution has a removal selectivity between Al₂O3 and SiO2 ranging between 50 and 70, and a removal selectivity between SiN and SiO2 ranging between 1.5 and 2.

In the fourth embodiment, the cleaning chemical solution includes HF with concentration ranging between 0.02% and 1%; a pH value ranging between 0.5 and 1.5; and a temperature ranging between 30° C. and 70° C. Accordingly, the corresponding cleaning chemical solution has a removal selectivity between Al₂O3 and SiO2 ranging between 300 and 600, and a removal selectivity between SiN and SiO2 ranging between 2 and 3.

From the above fine-tuned recipes of the cleaning chemical solution, when a base adjuster is used to tune the pH value of the cleaning chemical solution from a high higher pH value (such as 3) to a lower pH value (such as 1), the removal selectivity between Al₂O3 and SiO2 is increased from 10 or less up to 50 or more, and the removal selectivity between SiN and SiO2 is not monotonically changing, specifically decreased from 4˜5 to 0.5˜1.5, then increased up to 1.5˜2. When the temperature is increase from 20° C. and 25° C. to 30° C. and 70° C., the removal selectivity between Al₂O3 and SiO2 is substantially increased from 70 or less up to 300 or more, and the removal selectivity between SiN and SiO2 does not change much.

From the above data and the experiments, it is found that the temperature and pH value can be used to tune the removal selectivity of various residues to fit various cleaning processes. The first, second and third cleaning processes are implemented after the first, second and third etching processes. For example, the first etching process is a dry etching process to selectively remove silicon oxide; the second etching process is a wet etching process to selectively remove silicon oxide; and the third etching process is a dry etching process to selectively remove silicon nitride. Accordingly, to better remove the residues and minimize the damages to the first semiconductor layers 220A and the dielectric interposers 606, in some embodiment, the first cleaning process uses the fourth recipe in the fourth embodiment of the table in FIG. 7J; the second cleaning process uses the third recipe in the third embodiment of the table in FIG. 7J; and the third cleaning process uses the first recipe in the first embodiment of the table in FIG. 7J. In some embodiment, the first cleaning process uses the fourth recipe in the fourth embodiment of the table in FIG. 7J; the second cleaning process uses the second recipe in the third embodiment of the table in FIG. 7J; and the third cleaning process uses the first recipe in the first embodiment of the table in FIG. 7J.

In some other embodiments, the first and second cleaning processes use the first and second cleaning chemical solutions, respectively, with different pH values, different temperatures, or different HF concentrations, or a combination thereof. For example, the first and second cleaning processes use the first and second cleaning chemical solutions with a first and second pH values, respectively, such as the second pH value being greater than the first pH value. In another example, the first and second cleaning processes use the first and second cleaning chemical solutions with a first and second temperatures, respectively, such as the second temperature being greater than the first temperature.

In one embodiment, the first cleaning solution includes hydrofluoric acid (HF) with a volume concentration (volume ratio) ranging between 0.02% and 0.5%; water (H2O) with a volume concentration ranging between 94.5% and 99.88%; and an acid pH adjuster hydrogen chloride (HCl) with a volume concentration ranging between 0.1% and 5.0% to tune the pH value of the cleaning solution to a pH value ranging between 1 and 6, and furthermore with a solution temperature ranging between 25° C. and 80° C. Accordingly, the first semiconductor layers 220A have substantially reduced loss. In the disclosed embodiment with this recipe, the channel sheet bias T0-T1 of the topmost semiconductor layer 220A ranges between 0.1 nm and 1.5 nm; the channel sheet bias T0-T1 of the rest semiconductor layers 220A (other than the topmost one) ranges between 0.1 nm and 1 nm; the channel sheet angle bias a of the topmost semiconductor layer 220A ranges between 0.1 degree and 20 degree; and the channel sheet angle bias a of the rest semiconductor layers 220A (other than the topmost one) ranges between 0.1 degree and 15 degree. The parameters T0, Ti and α are described above in FIG. 7G.

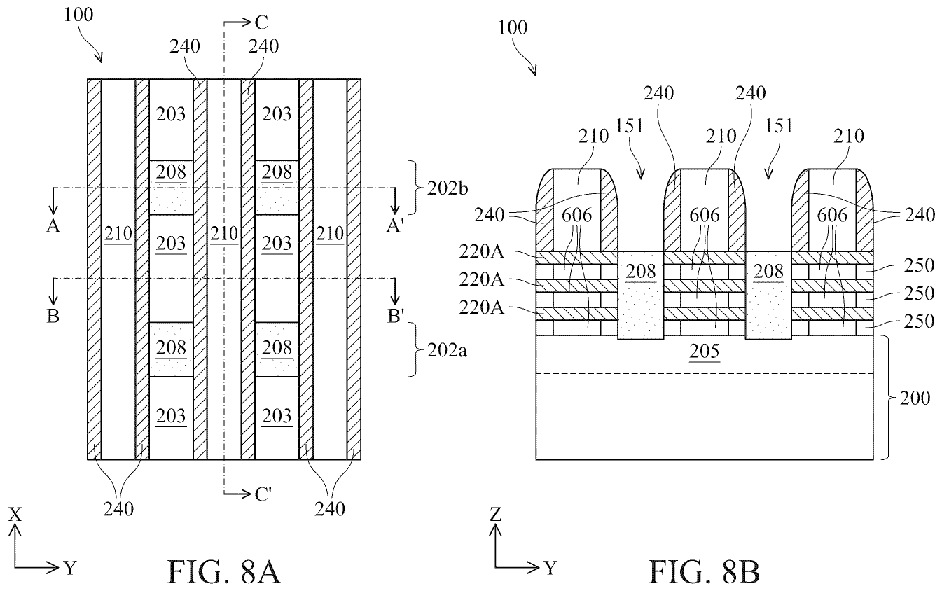

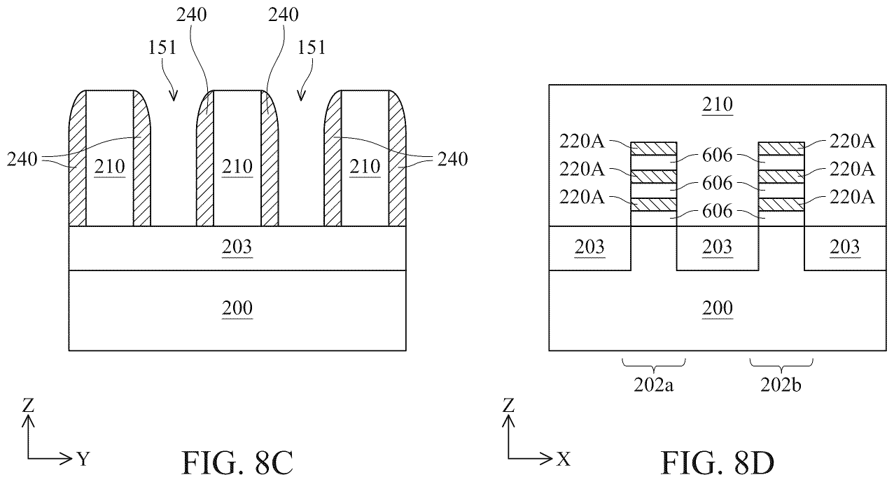

The following operations are described with references to FIGS. 8A to 16A in top views, and FIGS. 8B to 16B, 8C to 16C, and 8D to 16D in sectional views constructed according to various embodiments.

Referring to block 890 of FIG. 1C and FIGS. 8A-8D, the method 800 continues to form epitaxial source/drain features 208 in the trenches 151. In some embodiments, one source/drain feature is a source electrode, and the other source/drain feature is a drain electrode. The semiconductor layers 220A that extend from one source/drain feature 208 to the other source/drain feature 208 may form channels of the device structure 100. Multiple processes including growth processes may be employed to grow the epitaxial source/drain features 208. In the depicted embodiment, the epitaxial source/drain features 208 have top surfaces that are substantially aligned with the top surface of the topmost semiconductor layer 220A. However, in other embodiments, the epitaxial source/drain features 208 may alternatively have top surfaces that extend higher than the top surface of the topmost semiconductor layer 220A (e.g. in the Z-direction). In the depicted embodiment, the epitaxial source/drain features 208 occupy a lower portion of the trenches 151 (e.g. the portion defined by the inner spacers 250 and the semiconductor layers 220A), leaving an upper portion of the trenches 151 (e.g. the portion defined by the top spacers 240) open. In some embodiments, the epitaxial source/drain features 208 may merge together, for example, along the X-direction, to provide a larger lateral width than an individual epitaxial feature. In the depicted embodiments, as shown in FIG. 8A, the epitaxial source/drain features 208 are not merged.

The epitaxial source/drain features 208 may include any suitable semiconductor materials. For example, the epitaxial source/drain features 208 in an n-type GAA device may include Si, SiC, SiP, SiAs, SiPC, or combinations thereof; while the epitaxial source/drain features 208 in a p-type GAA device may include Si, SiGe, Ge, SiGeC, or combinations thereof. The source/drain features 208 may be doped in-situ or ex-situ. For example, the epitaxially grown Si source/drain features may be doped with carbon to form silicon:carbon (Si:C) source/drain features, phosphorous to form silicon:phosphor (Si:P) source/drain features, or both carbon and phosphorous to form silicon carbon phosphor (SiCP) source/drain features; and the epitaxially grown SiGe source/drain features may be doped with boron. One or more annealing processes may be performed to activate the dopants in the epitaxial source/drain features 208. The annealing processes may include rapid thermal annealing (RTA) and/or laser annealing processes.

The epitaxial source/drain features 208 directly interface with the continuous sidewall surfaces of the first semiconductor layers 220A. During the epitaxial growth, semiconductor materials grow from the exposed top surface 200a of the substrate 200 (e.g. the exposed top surface of doped region 205) as well as from the exposed side surfaces of the semiconductor layers 220A. It is noted that semiconductor materials do not grow from the surfaces of the inner spacers 250 and the top spacers 240 during the epitaxial growth process.

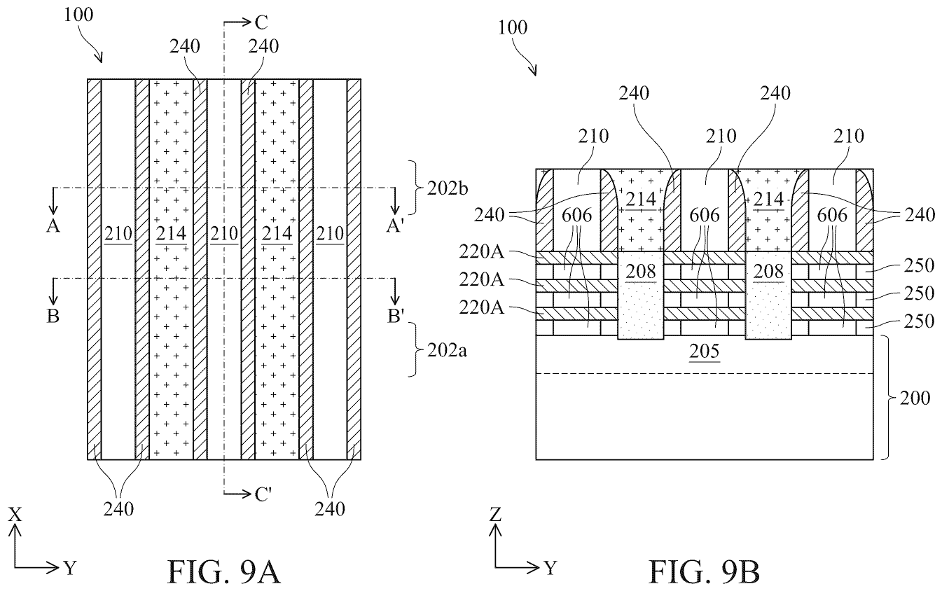

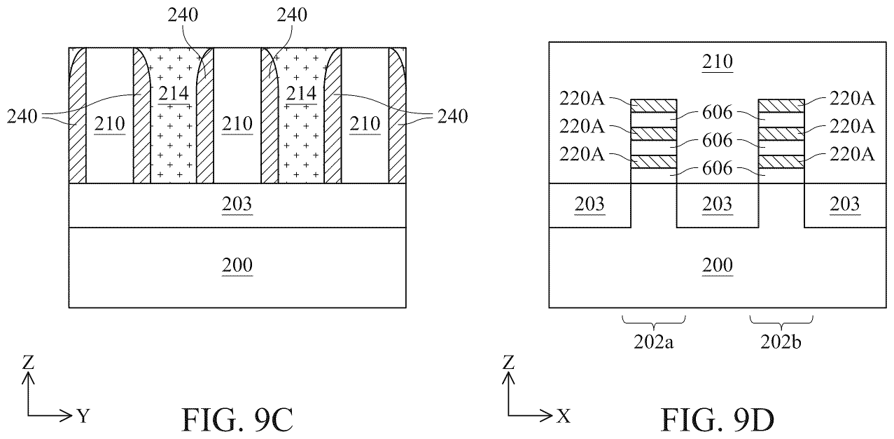

Referring to block 900 of FIG. 1C and FIGS. 9A-9D, an interlayer dielectric (ILD) layer 214 is formed over the epitaxial source/drain features 208 in the remaining spaces of the trenches 151, as well as vertically over the isolation features 203. The ILD layer 214 may also be formed in between the adjacent gate structures 210 along the Y-direction, and in between the source/drain features 208 along the X-direction. The ILD layer 214 may include a dielectric material, such as a high-k material, a low-k material, or an extreme low-k material. For example, the ILD layer 214 may include SiO2, SiOC, SiON, or combinations thereof. The ILD layer 214 may include a single layer or multiple layers, and may be formed by a suitable technique, such as CVD, FCVD, and/or spin-on techniques. After forming the ILD layer 214, a CMP process may be performed to remove excessive portions of the ILD layer 214, thereby planarizing the top surface of the ILD layer 214. Among other functions, the ILD layer 214 provides electrical isolation between the various components of the device structure 100.

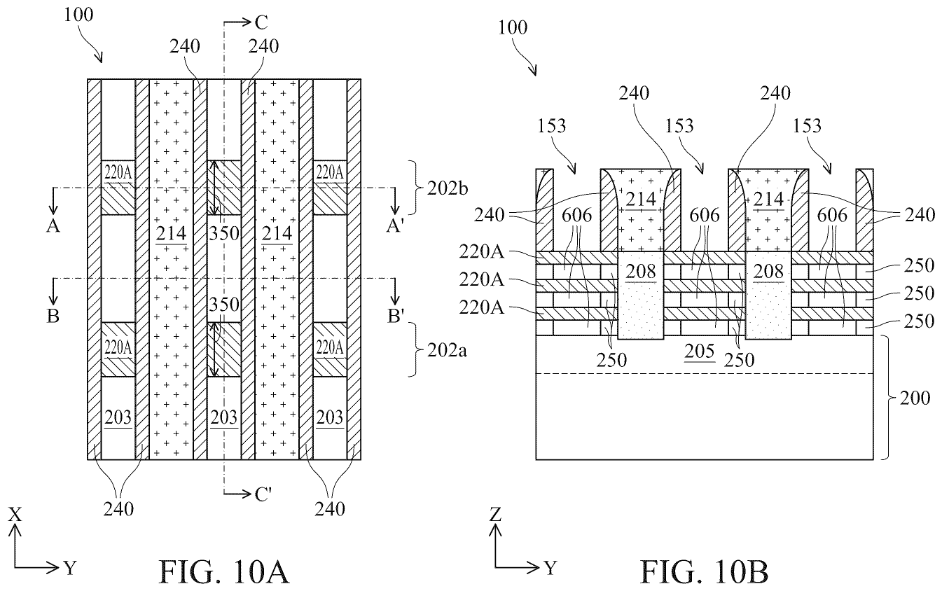

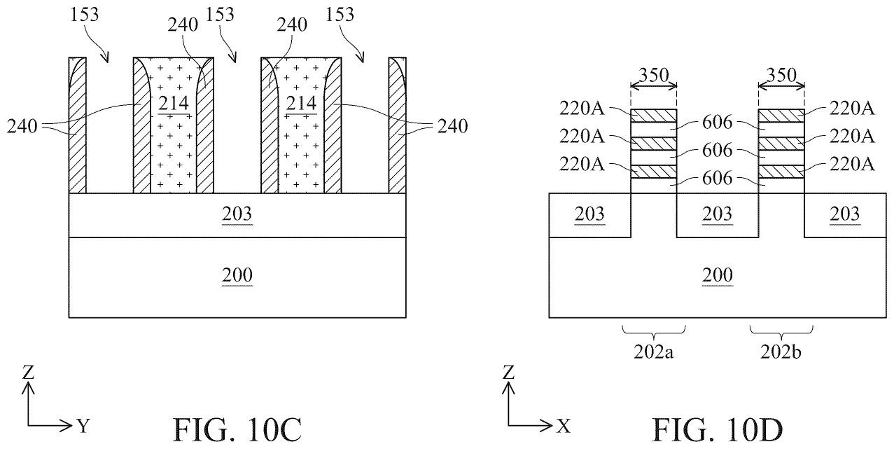

Referring to block 910 of FIG. 1C and FIGS. 10A-10D, the dummy gate structures 210 are selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structures 210. Then, the dummy gate structures 210 are selectively etched through the masking element. In some other embodiments, the top spacers 240 may be used as the masking element or a part thereof. For example, the dummy gate structures 210 may include polysilicon, the top spacers 240 and the inner spacers 250 may include dielectric materials, and the semiconductor layers 220A includes a semiconductor material. Therefore, an etch selectivity may be achieved by selecting appropriate etching chemicals, such that the dummy gate structures 210 may be removed without substantially affecting the features of the device structure 100. The removal of the dummy gate structures 210 creates gate trenches 153. The gate trenches 153 expose the top surfaces and the side surfaces of the first semiconductor layers 220A, and the dielectric interposers 606, as depicted in FIG. 10D. In other words, the first semiconductor layers 220A and the dielectric interposers 606 are exposed at least on two side surfaces in the gate trenches 153. Additionally, the gate trenches 153 also expose the top surfaces of the isolation features 203.

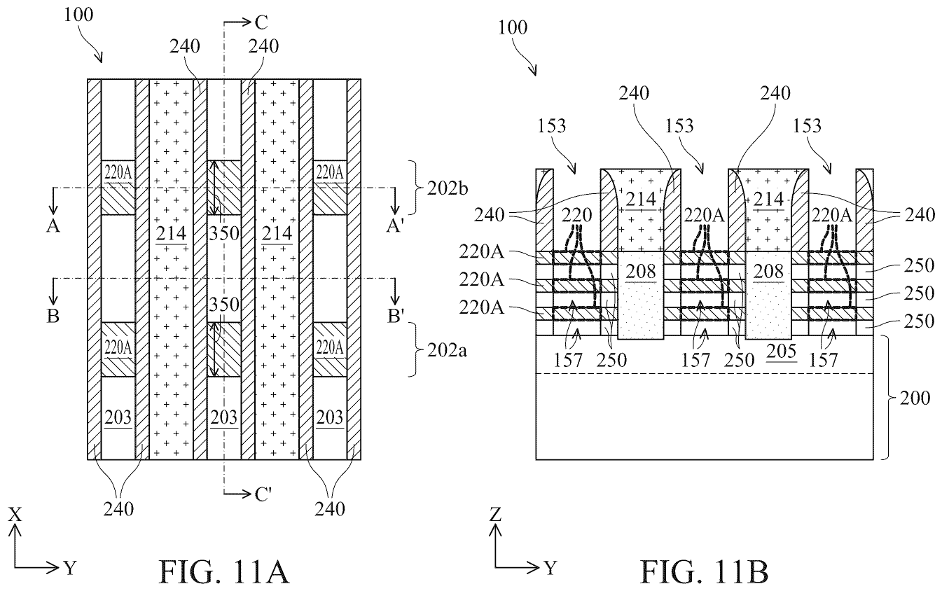

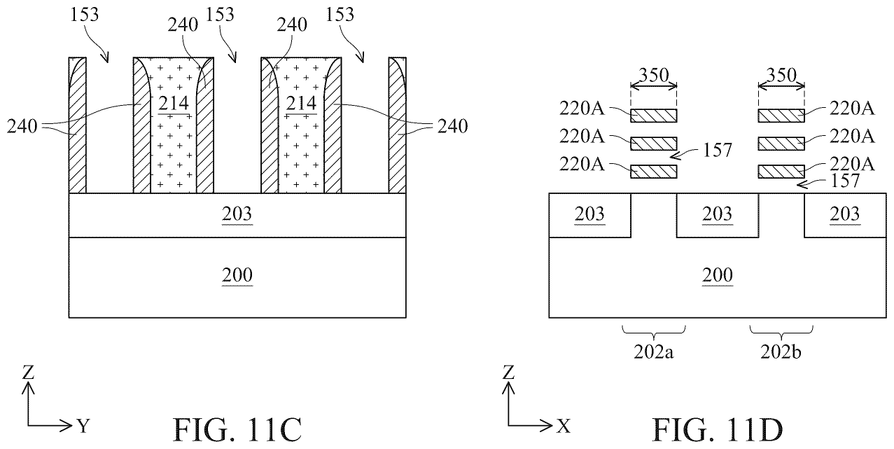

Referring to block 920 of FIG. 1C and FIGS. 11A-11D, the dielectric interposers 606 are further selectively removed through the gate trenches 153, therefore releasing the first semiconductor layers 220A as channels, for example using wet or dry etching process. The etching chemical is selected such that the dielectric interposers 606 has a sufficiently different etching rate as compared to the inner spacers 250 and the first semiconductor layers 220A. As a result, the first semiconductor layers 220A and the inner spacers 250 remain substantially unchanged. This selective etching process may include one or more etching steps. The etching process may be similar to the etching process at the block 868. For example, the etching process includes a wet etching step using HF solution to selectively remove the dielectric interposers 606.

As illustrated in FIGS. 11A-11D, in the present embodiment, the removal of the dielectric interposers 606 forms suspended semiconductor layers 220A and openings 157 in between the vertically adjacent layers (e.g. in the Z-direction), thereby exposing the top and bottom surfaces of the first semiconductor layers 220A. Each of the first semiconductor layers 220A are now exposed circumferentially in the X-Z plane. In addition, the portion of the doped regions 205 beneath the first semiconductor layers 220A are also exposed in the openings 157. In some other embodiments however, the removal process only removes some but not all of the second semiconductor layers 220B.

In the examples depicted in FIGS. 10A-10D and FIGS. 11A-11D, the gate trench 153 and the opening 157 vertically adjacent to the gate trench 153 (e.g. in the Z-direction) collectively form an opening having a vertical profile. In other words, the opening collectively formed by the gate trench 153 and its corresponding opening 157 have vertical sidewalls. In some embodiments, such openings having the vertical sidewalls may be formed by a plurality of etch processes. For example, the etch chemistry of the etch process used to remove the dummy gate structures 210 and thereby form the gate trenches 153 (e.g. in FIGS. 10A-10D) may include hydrogen bromide (HBr) combined with chlorine (Cl₂), tetrafluoromethane (CF₄), oxygen, or a combination thereof. Furthermore, the etch process used to selectively remove the dielectric interposers 606 and thereby form the openings 157 (e.g. in FIGS. 11A-11D) may have an initial etch chemistry including hydrogen bromide (HBr) combined with chlorine (Cl₂), oxygen, or a combination thereof. This initial etch chemistry is followed by a subsequent etch chemistry including hydrogen bromide (HBr) combined with tetrafluoromethane (CF₄), oxygen, or a combination thereof that induces the vertical profile of the opening collectively formed by the gate trench 153 and its corresponding opening 157. In an alternative embodiment, the initial etch chemistry is followed by a subsequent wet etch chemistry using HF solution to selectively remove the dielectric interposers 606. As described in further detail below, in other embodiments, however, the opening collectively formed by a gate trench 153 and its corresponding opening 157 may have a tapered profile. Such a tapered profile may be achieved by omitting the above-described subsequent etch chemistry that includes hydrogen bromide (HBr) combined with tetrafluoromethane (CF₄), oxygen, or a combination thereof. In such examples, a gate structure that is subsequently formed in the tapered opening has a tapered profile as well.

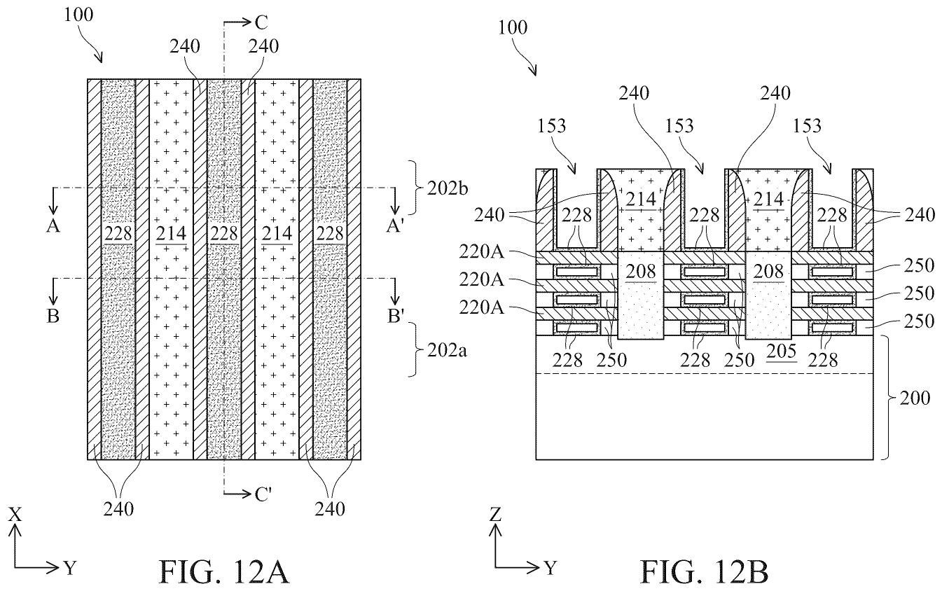

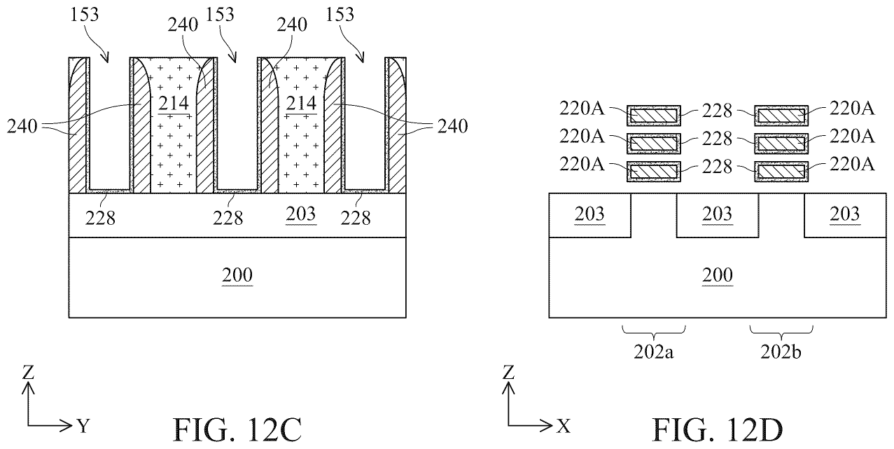

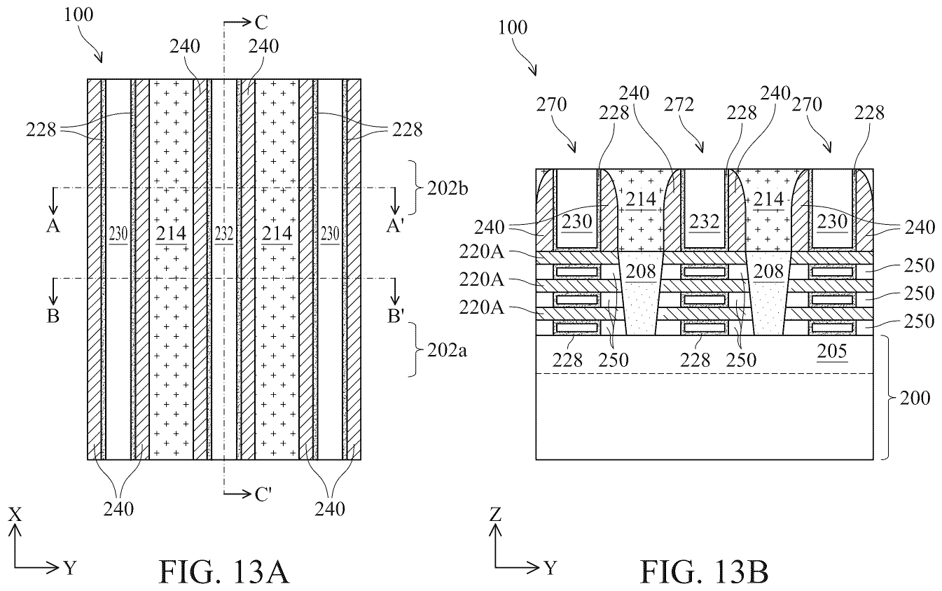

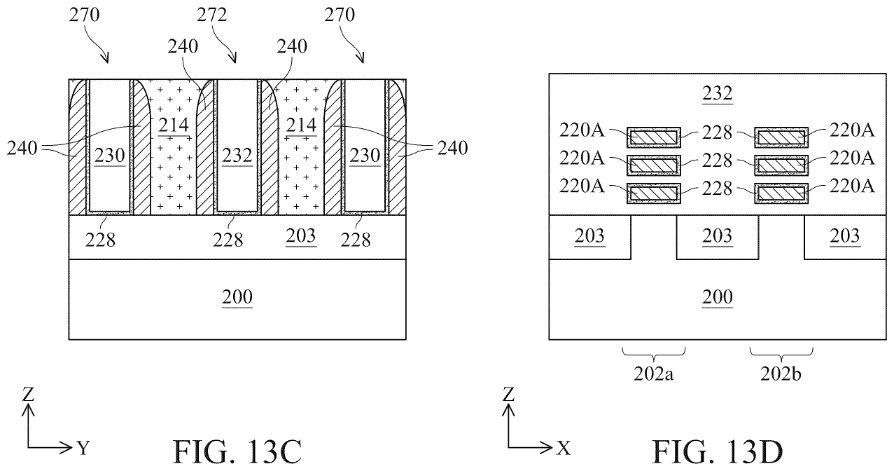

Referring to blocks 930 and 940 of FIG. 1C, FIGS. 12A-12D, and FIGS. 13A-13D, a gate structure is formed. The gate structure includes a gate dielectric layer, and a gate electrode disposed over the gate dielectric layer. For example, the gate structure may include a polysilicon gate electrode over a SiON gate dielectric layer. As another example, the gate structure may include a metal gate electrode over a high-k dielectric layer. In some instances, a refractory metal layer may interpose between the metal gate electrode (such as an aluminum gate electrode) and the high-k dielectric layer. As yet another example, the gate structure may include silicide. In the depicted embodiment, the gate structures each includes a gate dielectric layer 228 and a gate electrode that includes one or more metal layers 230, 232, as illustrated in FIGS. 13A˜13D. The gate dielectric layers 228 are formed between the metal layers 230, 232 and the channels (the semiconductor layers 220A).

In some embodiments, the gate dielectric layers 228 are formed conformally on the device structure 100 (see FIGS. 12A-12D). The gate dielectric layers 228 at least partially fill the gate trenches 153. In some embodiments, dielectric interfacial layers may be formed over the semiconductor layers 220A prior to forming the gate dielectric layers 228. Such dielectric interfacial layers improve the adhesion between the semiconductor layers 220A and the gate dielectric layers 228. In the examples depicted in this disclosure, such dielectric interfacial layers are omitted. Instead, in the embodiments shown, the gate dielectric layers 228 is formed around the exposed surfaces of each of the semiconductor layers 220A, such that they wrap around each of the semiconductor layers 220A in 360 degrees. Additionally, the gate dielectric layers 228 also directly contact sidewalls of the inner spacers 250 and sidewalls of the top spacers 240. The gate dielectric layers 228 may include a dielectric material having a dielectric constant greater than a dielectric constant of SiO2, which is approximately 3.9. For example, the gate dielectric layers 228 may include hafnium oxide (HfO₂), which has a dielectric constant in a range from about 18 to about 40. As various other examples, the gate dielectric layers 228 may include ZrO₂, Y₂O3, La₂O₅, Gd₂O₅, TiO₂, Ta₂O5, HfErO, HfLaO, HfYO, HfGdO, HfAIO, HfZrO, HTIO, HfTaO, SrTiO, or combinations thereof. The formation of the gate dielectric layers 228 may be by any suitable processes, such as CVD, PVD, ALD, or combinations thereof.

Referring to block 940 of FIG. 1C and FIGS. 13A-13D, metal layers 230, 232 are formed over the gate dielectric layers 228 to fill the remaining spaces of the gate trenches 153. The metal layers 230, 232 may include any suitable materials, such as titanium nitride (TiN), tantalum nitride (TaN), titanium aluminide (TiAl), titanium aluminum nitride (TiAIN), tantalum aluminide (TaAl), tantalum aluminum nitride (TaAIN), tantalum aluminum carbide (TaAIC), tantalum carbonitride (TaCN), aluminum (Al), tungsten (W), copper (Cu), cobalt (Co), nickel (Ni), platinum (Pt), or combinations thereof. In some embodiments, a CMP is performed to expose a top surface of the ILD layer 214. The dielectric layers 228 and the metal layers 230 collectively form the gate structures 270, while the dielectric layers 228 and the metal layers 232 collectively form gate structure 272. Each of the gate structures 270, 272 engages multiple nanochannels 220A.

The gate electrode may include Ti, Ag, Al, TiAIN, TaC, TaCN, TaSiN, Mn, Zr, TiN, TaN, Ru, Mo, Al, WN, Cu, W, Ru, Co, or any suitable conductive materials. In some embodiments, different metal materials are used for pFET and nFET devices with respective work functions to enhance device performances and reduce threshold voltages. For examples, the gate structure 270 is a gate structure of pFET devices and the gate structure 272 is a gate structure of nFET devices.

The gate electrode may include multiple conductive materials, such as a work function metal layer different for pFET and nFET devices, and a fill metal layer. In some embodiments, the gate electrode includes a capping layer, a blocking layer, a work function metal layer, and a filling metal layer. In furtherance of the embodiments, the capping layer includes titanium nitride, tantalum nitride, or other suitable material, formed by a proper deposition technique such as ALD. The blocking layer includes titanium nitride, tantalum nitride, or other suitable material, formed by a proper deposition technique such as ALD. In various embodiments, the filling metal layer includes aluminum, tungsten, copper or other suitable metal. The filling metal layer is deposited by a suitable technique, such as PVD, plating or a combination thereof.

The work functional metal layer includes a conductive layer of metal or metal alloy with proper work function such that the corresponding FET is enhanced for its device performance. The work function (WF) metal layer is different in composition for a pFET device and a nFET device, therefore being referred to as an p-type WF metal and a n-type WF metal, respectively. Particularly, an n-type WF metal is a metal having a first work function such that the threshold voltage of the associated nFET is reduced. The n-type WF metal is close to the silicon conduction band energy (Ec) or lower work function, presenting easier electron escape. For example, the n-type WF metal has a work function of about 4.2 eV or less. A p-type WF metal is a metal having a second work function such that the threshold voltage of the associated pFET is reduced. The p-type WF metal is close to the silicon valence band energy (Ev) or higher work function, presenting strong electron bonding energy to the nuclei. For example, the p-type work function metal has a WF of about 5.2 eV or higher. In some embodiments, the n-type WF metal includes tantalum (Ta). In other embodiments, the n-type WF metal includes titanium aluminum (TiAl), titanium aluminum nitride (TiAIN), or combinations thereof. In other embodiments, the n-metal include Ta, TiAl, TiAIN, tungsten nitride (WN), or combinations thereof. In some embodiments, the p-type WF metal includes titanium nitride (TiN) or tantalum nitride (TaN). In other embodiments, the p-metal include TiN, TaN, tungsten nitride (WN), titanium aluminum (TiAl), or combinations thereof. The work function metal is deposited by a suitable technique, such as PVD. The n-type WF metal or the p-type WF metal may include various metal-based films as a stack for optimized device performance and processing compatibility.

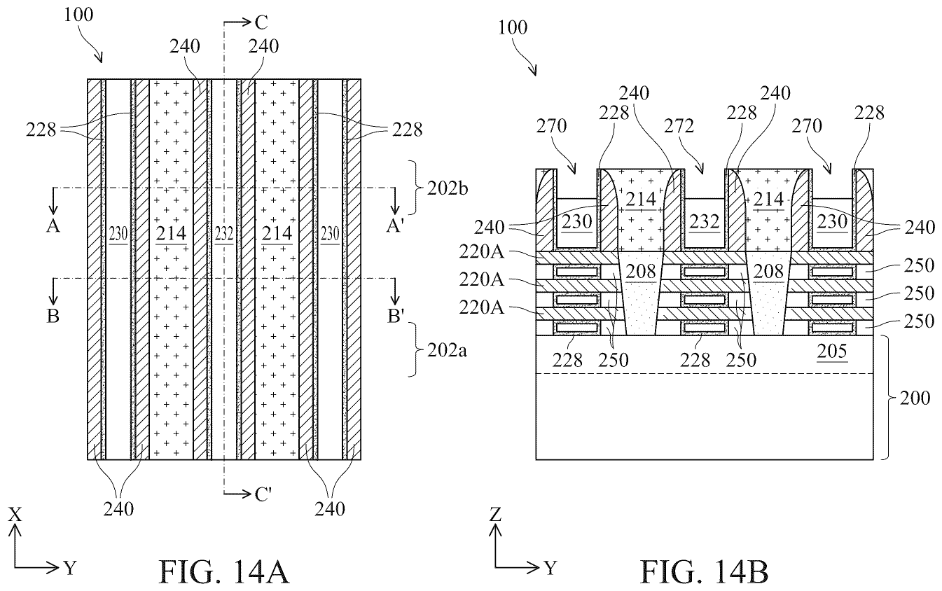

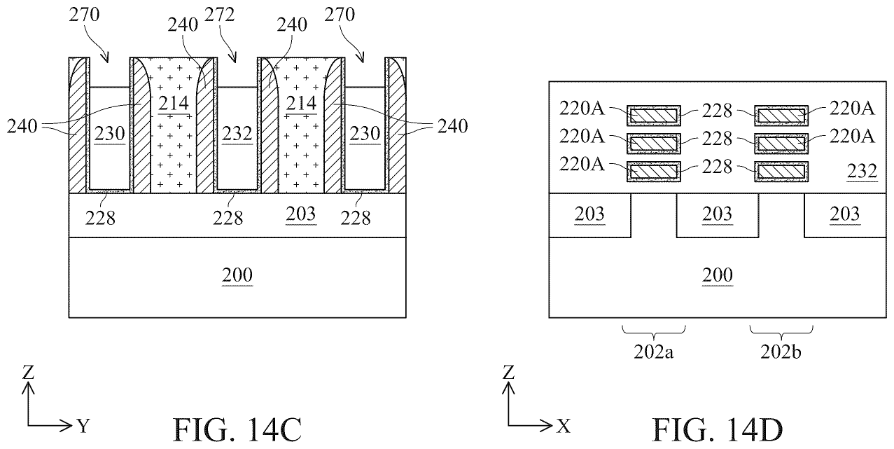

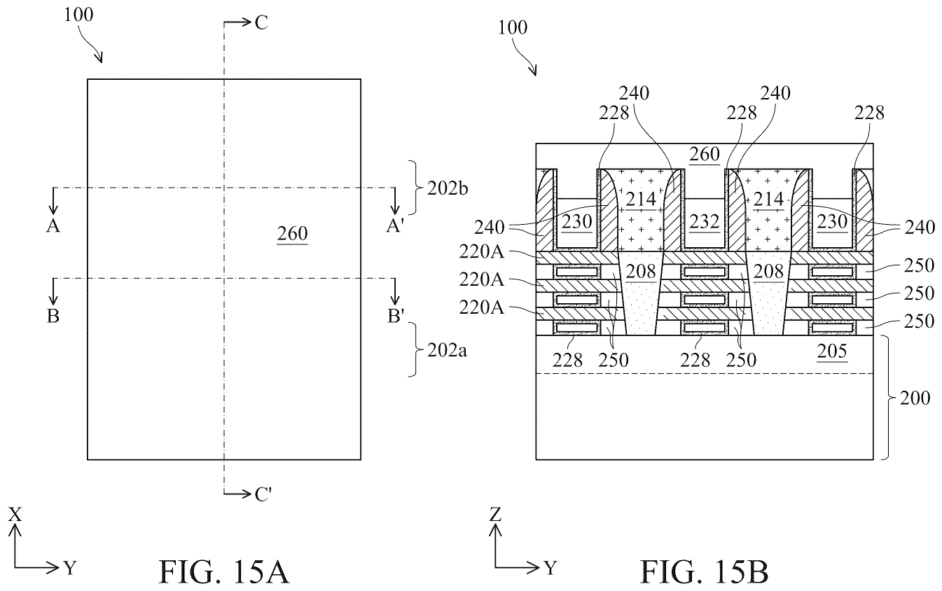

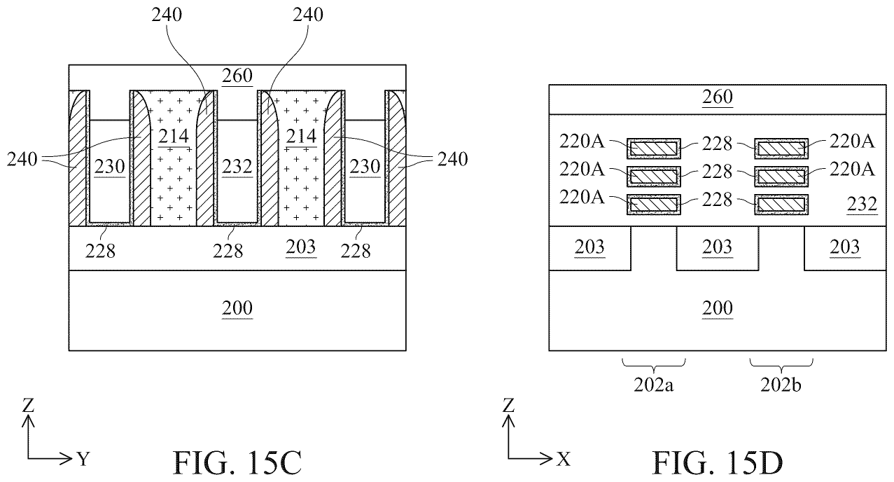

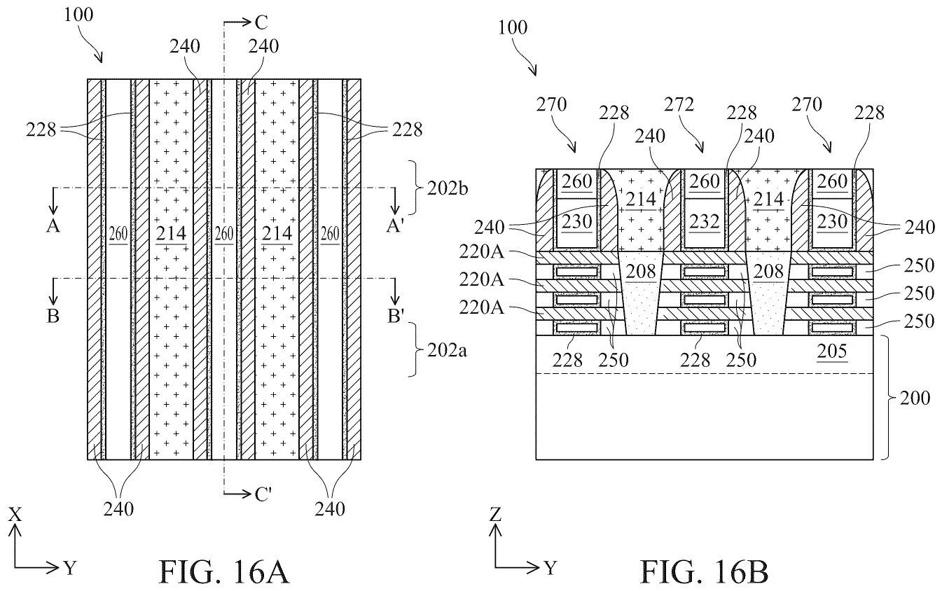

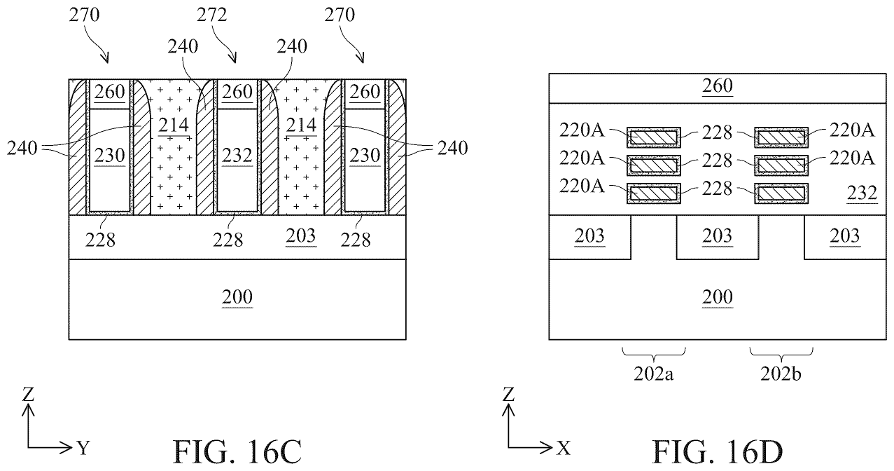

In some embodiments, a gate top hard mask layer 260 may optionally be formed over the gate structures 270, 272. For example, referring to FIGS. 14A-14D, the metal layers 230, 232 may optionally be recessed, such that a top surface of the metal layers 230, 232 extends below a top surface of the ILD layer 214. Subsequently, as illustrated in FIGS. 15A-15D, a gate top hard mask layer 260 is formed over the device structure 100 such that it covers the gate structures 270, 272 (specifically, the metal layers 230, 232), the ILD layers 214, and fills the space created by the recess process. A CMP may be conducted to planarize the top surface of the gate top hard mask layer 260. In some embodiments, as illustrated in FIGS. 16A-16D, the CMP exposes the top surfaces of the ILD layers 214, the top surfaces of the top spacers 240, and the top surfaces of the gate dielectric layers 228. The gate top hard mask layers 260 may include a dielectric material, such as SiO₂, SiOC, SiON, SiOCN, nitride-based dielectric, metal oxide dielectric, HfO₂, Ta₂O₅, TiO₂, ZrO₂, Al₂O₃, Y₂O₃, or combinations thereof. The gate top hard mask layer 260 protects the gate structures 270, 272 in the subsequent etching processes to form the source/drain contact features, and also insulates the gate structures 270, 272. However, in some other embodiments (not shown), recessing of the metal layers 230, 232 and/or the formation of the gate top hard mask layers 260 is omitted. In some embodiments, the gate structure 270 is a gate structure of pFET devices and the gate structure 272 is a gate structure of nFET devices.

As illustrated in FIG. 7B, the channels (or the first semiconductor layers) 220A keep the profile without rounding issue. Specifically, the channels 220A have a thickness TO at the main portions and a thickness T1 at the edges. The difference ΔT=T0-T1 is less than 2 nm. In other words, the loss ΔT is less than 2 nm if any. In some examples, the difference ΔT ranges between 0.1 nm and 1.5 nm. The top surfaces of the first semiconductor layers 220A are substantially coplanar with the X-Y plane. The edge portions of the first semiconductor layers 220A have top surfaces with an angle α to the X-Y plane. In the disclosed embodiment, the angle α is less than 20 degrees. In some examples, the angle α ranges between 0.1 degree and 20 degree. In some examples, the angle α ranges between 0.1 degree and 10 degree.

The method 800 may include other processing steps implemented before, during and/or after the various operations described above. For example, the method 800, at a block 950 of FIG. 1C, includes forming an interconnect structure to connect various FETs and other devices into an integrated circuit. The interconnect structure includes contacts, vias and metal lines through a suitable process. In the copper interconnect structure, the conductive features include copper and may further include a barrier layer. The copper interconnect structure is formed by a damascene process. A damascene process includes depositing an ILD layer; patterning the ILD layer to form trenches; depositing various materials (such as a barrier layer and copper); and performing a CMP process. A damascene process may be a single damascene process or a dual damascene process. The deposition of the copper may include PVD to form a seed layer and plating to form bulk copper on the copper seed layer. Other metals, such as ruthenium, cobalt, tungsten or aluminum, may be used to form to form the interconnection structure. In some embodiments, prior to filling conductive material in contact holes, silicide may be formed on the sources and drains to further reduce the contact resistance. The silicide includes silicon and metal, such as titanium silicide, tantalum silicide, nickel silicide or cobalt silicide. The silicide may be formed by a process referred to as self-aligned silicide (or salicide). The process includes metal deposition, annealing to react the metal with silicon, and etching to remove unreacted metal. In some other embodiments, some other metal, such as ruthenium or cobalt, may be used for contacts and/or vias.

The present disclosure provides a semiconductor structure having GAA structure and a method making the same with designed cleaning chemicals and cleaning procedure. Though not intended to be limiting, embodiments of the present disclosure offer benefits for semiconductor processing and semiconductor devices. For example, the disclosed method reduces the metal residues and reduces the damages to the channels, therefore enhancing the device performance.

In one example aspect, the present disclosure provides a method of semiconductor fabrication. The method includes forming a stack including first semiconductor layers and second semiconductor layers over a semiconductor substrate, wherein the first semiconductor layers and the second semiconductor layers have different material compositions and alternate with one another within the stack; forming a dummy gate structure over the stack; forming a gate spacer on sidewalls of the dummy gate structure; recessing source/drain regions of the stack, resulting in source/drain trenches; selectively removing the second semiconductor layers of the stack, resulting in first gaps among the first semiconductor layers; depositing a first dielectric material to fill in the first gaps; performing a first etching process to the first dielectric material, thereby forming dielectric interposers among the first semiconductor layers; performing a first cleaning process using a first cleaning chemical solution; performing a second etching process to laterally recess the dielectric interposers, resulting in second gaps among the first semiconductor layers; performing a second cleaning process using a second cleaning chemical solution; forming inner spacers of a second dielectric material in the second gaps; and performing a third cleaning process using a third cleaning chemical solution, wherein the first dielectric material and the second dielectric material are different in composition, and wherein each of the first, second and third cleaning chemical solutions includes hydrofluoric acid and water.

In another example aspect, the present disclosure provides a method of semiconductor fabrication. The method includes forming a stack including first semiconductor layers and second semiconductor layers over a semiconductor substrate, wherein the first semiconductor layers and the second semiconductor layers have different material compositions and alternate with one another within the stack; forming a dummy gate structure over the stack; forming a gate spacer on sidewalls of the dummy gate structure; recessing source/drain regions of the stack, resulting in source/drain trenches; selectively removing the second semiconductor layers of the stack in the source/drain trenches, resulting in first gaps among the first semiconductor layers; depositing a first dielectric material to fill in the first gaps; performing a first etching process to the first dielectric material, thereby forming dielectric interposers among the first semiconductor layers; performing a first cleaning process using a first cleaning chemical solution; performing a second etching process to laterally recess the dielectric interposers, resulting in second gaps among the first semiconductor layers; and performing a second cleaning process using a second cleaning chemical solution being different from the first cleaning chemical solution.

In yet another example aspect, the present disclosure provides a method of semiconductor fabrication. The method includes forming a stack including first semiconductor layers and second semiconductor layers over a semiconductor substrate, wherein the first semiconductor layers and the second semiconductor layers have different material compositions and alternate with one another within the stack; forming a dummy gate structure over the stack; forming a gate spacer on sidewalls of the dummy gate structure; recessing source/drain regions of the stack, resulting in source/drain trenches; selectively removing the second semiconductor layers of the stack, resulting in first gaps among the first semiconductor layers; depositing a first dielectric material to fill in the first gaps; performing a first etching process to the first dielectric material, thereby forming dielectric interposers among the first semiconductor layers; performing a first cleaning process using a first cleaning chemical solution with a first pH value; performing a second etching process to laterally recess the dielectric interposers, resulting in second gaps among the first semiconductor layers; and performing a second cleaning process using a second cleaning chemical solution with a second pH value being different from the first pH value, wherein each of the first and second cleaning chemical solutions includes hydrofluoric acid (HF) and a pH adjuster.

In yet another example aspect, the present disclosure provides a semiconductor structure. The semiconductor structure includes a substrate having a top surface; an active region on the substrate; an isolation structure surrounded the active region; a plurality of channels vertically stacked over one another on the substrate within the active region; a first and second source/drain (S/D) features interposed the channels and connected to each of the channels; and a gate stack disposed on the channels and extending to wrap around the each of the channels, wherein the each of the channels includes an edge portion having a top surfaces with an angle α to the top surface of the substrate, and wherein the angle α ranges between 0.1 degree and 10 degree.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack including first semiconductor layers and second semiconductor layers over a semiconductor substrate, wherein the first semiconductor layers and the second semiconductor layers have different material compositions and alternate with one another within the stack;
forming a dummy gate structure over the stack;
forming a gate spacer on sidewalls of the dummy gate structure;
recessing source/drain regions of the stack, resulting in source/drain trenches;
selectively removing the second semiconductor layers of the stack, resulting in first gaps among the first semiconductor layers;
depositing a first dielectric material to fill in the first gaps;
performing a first etching process to the first dielectric material, thereby forming dielectric interposers among the first semiconductor layers;
performing a first cleaning process using a first cleaning chemical solution;
performing a second etching process to laterally recess the dielectric interposers, resulting in second gaps among the first semiconductor layers;
performing a second cleaning process using a second cleaning chemical solution;
forming inner spacers of a second dielectric material in the second gaps; and
performing a third cleaning process using a third cleaning chemical solution, wherein the first dielectric material and the second dielectric material are different in composition, and wherein each of the first, second and third cleaning chemical solutions includes hydrofluoric acid and water.

2. The method of claim 1, wherein the forming of the inner spacers in the second gaps further includes:
depositing the second dielectric material to fill in the second gaps; and
performing a third etching process to the second dielectric material.

3. The method of claim 1, wherein the first dielectric material includes silicon oxide, and the second dielectric material includes silicon nitride.

4. The method of claim 1, wherein each of the first, second and third cleaning chemical solutions further includes a pH adjuster.

5. The method of claim 4, wherein the pH adjuster includes a base pH adjuster having ammonium hydroxide (NH₄OH).

6. The method of claim 4, wherein the pH adjuster includes an acid pH adjuster having at least one of hydrogen chloride (HCl), phosphoric acid (H3PO4), sulfuric acid (H2SO4), and a combination thereof.

7. The method of claim 1, wherein each of the first, second and third cleaning chemical solutions includes hydrofluoric acid (HF) with a volume concentration ranging between 0.02% and 20%, and water with a volume concentration ranging between 60% and 99.8%.

8. The method of claim 1, wherein the first cleaning chemical solution includes hydrofluoric acid (HF) with a volume concentration ranging between 0.02% and 0.5%; water (H2O) with a volume concentration ranging between 94.5% and 99.88%; an acid pH adjuster hydrogen chloride (HCl) with a volume concentration ranging between 0.1% and 5.0% the first cleaning chemical solution with a pH value ranging between 1 and 6; and a solution temperature ranging between 25° C. and 80° C.

9. The method of claim 1, wherein
the first cleaning chemical solution includes hydrofluoric acid (HF) with a volume concentration ranging between 0.02% and 1%; a pH value ranging between 0.5 and 1.5; and a solution temperature ranging between 30° C. and 70° C.;
the second cleaning chemical solution includes hydrofluoric acid with a volume concentration ranging between 0.02% and 1%; a pH value ranging between 0.5 and 1.5; and a solution temperature ranging between 20° C. and 25° C.; and
the third cleaning chemical solution includes hydrofluoric acid with a volume concentration ranging between 0.02% and 1%; a pH value ranging between 2.5 and 4.0; and a solution temperature ranging between 20° C. and 25° C.

10. A method, comprising:
forming a stack including first semiconductor layers and second semiconductor layers over a semiconductor substrate, wherein the first semiconductor layers and the second semiconductor layers have different material compositions and alternate with one another within the stack;
forming a dummy gate structure over the stack;
forming a gate spacer on sidewalls of the dummy gate structure;
recessing source/drain regions of the stack, resulting in source/drain trenches;
selectively removing the second semiconductor layers of the stack in the source/drain trenches, resulting in first gaps among the first semiconductor layers;
depositing a first dielectric material to fill in the first gaps;
performing a first etching process to the first dielectric material, thereby forming dielectric interposers among the first semiconductor layers;
performing a first cleaning process using a first cleaning chemical solution;
performing a second etching process to laterally recess the dielectric interposers, resulting in second gaps among the first semiconductor layers; and
performing a second cleaning process using a second cleaning chemical solution being different from the first cleaning chemical solution.

11. The method of claim 10, wherein
each of the first and second cleaning chemical solutions includes hydrofluoric acid with a volume concentration (volume ratio) ranging between 0.02% and 20%, water (H2O) with a volume concentration ranging between 60% and 99.8%, and one of a base pH adjuster and an acid pH adjuster; and
the first cleaning chemical solution includes a first solution temperature, and the second cleaning chemical solution includes a second solution temperature being less than the first solution temperature.

12. The method of claim 11, wherein
the first cleaning chemical solution includes hydrofluoric acid with a volume concentration ranging between 0.02% and 1%; a pH value ranging between 0.5 and 1.5; and a solution temperature ranging between 30° C. and 70° C.; and
the second cleaning chemical solution includes hydrofluoric acid with a volume concentration ranging between 0.02% and 1%; a pH value ranging between 0.5 and 1.5; and a solution temperature ranging between 20° C. and 25° C.

13. The method of claim 12, further comprising:
depositing a second dielectric material to fill in the second gaps;
performing a third etching process to the second dielectric material; and
performing a third cleaning process using a third cleaning chemical solution, wherein the first dielectric material and the second dielectric material are different in composition, and wherein the third cleaning chemical solutions includes hydrofluoric acid and water.

14. The method of claim 13, wherein the first dielectric material includes silicon oxide, and the second dielectric material includes silicon nitride.

15. The method of claim 14, wherein the third cleaning chemical solution includes hydrofluoric acid with a volume concentration ranging between 0.02% and 1%; a pH value ranging between 2.5 and 4.0; and a solution temperature ranging between 20° C. and 25° C.

16. The method of claim 10, wherein
each of the first and second cleaning chemical solutions includes hydrofluoric acid with a volume concentration (volume ratio) ranging between 0.02% and 20%, water (H2O) with a volume concentration ranging between 60% and 99.8%, and one of a base pH adjuster and an acid pH adjuster; and
the second pH value is greater than the first pH value.

17. The method of claim 16, wherein the first cleaning chemical solution includes a first solution temperature, and the second cleaning chemical solution includes a second solution temperature being less than the first solution temperature.

18. The method of claim 17, wherein
the first solution temperature ranges between 30° C. and 70° C.; and
the second solution temperature ranges between 20° C. and 25° C.

19. A semiconductor structure, comprising:
a substrate having a top surface;
an active region on the substrate;
an isolation structure surrounded the active region;
a plurality of channels vertically stacked over one another on the substrate within the active region;
a first and second source/drain (S/D) features interposed the channels and connected to each of the channels; and
a gate stack disposed on the channels and extending to wrap around the each of the channels, wherein the each of the channels includes an edge portion having a top surfaces with an angle α to the top surface of the substrate, and wherein the angle α ranges between 0.1 degree and 10 degree.

20. The semiconductor structure of claim 19, wherein
the each of the channels includes a main portion having a first thickness T1;
the edge portion includes a second thickness T2; and
a difference between T1 and T2 is less than 2 nm.
